(19) United States
(12) Patent Application Publication
(10) Pub. No.: US 2014/0205816 A1
(43) Pub. Date: Jul. 24, 2014

(54) DICING-TAPE-INTEGRATED ADHESIVE SHEET, SEMICONDUCTOR DEVICE, MULTILAYERED CIRCUIT BOARD AND ELECTRONIC COMPONENT

(71) Applicant: Kenzo Maejima, Tokyo (JP)

(72) Inventor: Kenzo Maejima, Tokyo (JP)

(73) Assignee: SUMITOMO BAKELITE CO., LTD., Tokyo (JP)

(21) Appl. No.: 14/131,156

(22) PCT Filed: Jul. 6, 2012
(86) PCT No.: PCT/JP2012/067374

§ 371 Date: Jan. 6, 2014

(30) Foreign Application Priority Data
Jul. 8, 2011 (JP) 2011-152370

(51) Int. Cl. H01L 21/683; C09J 7/02

(52) U.S. Cl. CPC H01L 21/6836; C09J 7/02
USPC 428/200; 428/354; 428/345

(57) ABSTRACT

According to the present invention, a dicing-tape-integrated adhesive sheet is provided in which connection between terminals of opposing members and encapsulating of voids between the members can be simultaneously performed and thus excellent workability is achieved. The dicing-tape-integrated adhesive sheet of the present invention has a laminated structure including an adhesive film which has a first terminal of a support body and a second terminal of an adherend that are electrically connected using solder and by which the support body and the adherend are adhered to each other and a dicing tape. When it is assumed that an adhesion temperature when the adhesive film is adhered to a surface on which the first terminal of the support body is formed is T[° C.], a pressure applied to the adhesive film is P[MPa], and a melt viscosity of the adhesive film at the adhesion temperature is η[Pa·s], a relationship of 1.2×10³≦(T×P)/η≦1.5×10⁹ is satisfied.

### TECHNICAL FIELD

The present invention relates to a dicing-tape-integrated adhesive sheet, a semiconductor device, a multilayered circuit board, and an electronic component.

Priority is claimed on Japanese Patent Application No. 2011-152370, filed on Jul. 8, 2011, the content of which is incorporated herein by reference.

### BACKGROUND ART

Recently, with the demand for high functionality and miniaturization (reductions in weight, thickness, length, and size) of electronic devices, high-density integration and high-density packaging of electronic components such as a semiconductor package have been developed, and miniaturization and increase in the number of pins of the electronic components have proceeded. In order to obtain electrical connection of the electronic components, soldering is used.

As for the soldering, for example, conductive bonding portions between semiconductor chips, conductive bonding portions between a semiconductor chip such as a package mounted in a flip chip and a circuit board, and conductive bonding portions between circuit boards may be employed. In the soldered portion, in order to ensure electrical connection strength and mechanical connection strength, an encapsulating resin called an underfill material is typically injected (underfill encapsulating).

In a case where a void (gap) generated by the soldered portion is reinforced by a liquid encapsulating resin (underfill material), the liquid encapsulating resin (underfill material) is supplied after soldering and is cured to reinforce the soldered portion. However, due to the reduction in thickness and miniaturization of electronic components, the pitch and the gap of the soldered portion are reduced. Therefore, even when the liquid encapsulating resin is supplied to the soldered portion after the soldering, the liquid encapsulating resin (underfill material) does not spread to the gaps, and there is a problem in that it is difficult to completely fill the gaps.

For this problem, a method of collectively performing electrical connection and adhesion between terminals via an anisotropic conductive film is known. For example, a method in which an adhesive film containing conductive particles is interposed between members and is subjected to thermocompression bonding to interpose the conductive particles between the terminals of both the members and fill a resin component in other portions, and a method in which conductive particles are allowed to come into contact with each other to obtain electrical connection of the part are described (for example, Patent Documents 1 and 2).

However, in these methods, since the conductive particles are present between the adjacent terminals, it is difficult to ensure insulation between the adjacent terminals. In addition, since voids are present between the adjacent terminals, it is difficult to ensure reliability of an electronic component or a semiconductor device.

### CITATION LIST

### Patent Literature

[Patent Document 1] Japanese Unexamined Patent Application, First Publication No. S61-276873
[Patent Document 2] Japanese Unexamined Patent Application, First Publication No. H9-31419

### SUMMARY OF INVENTION

### Technical Problem

An object of the present invention is to provide a dicing-tape-integrated adhesive sheet in which connection between terminals of opposing members and encapsulating of voids between the members can be simultaneously performed and thus excellent workability is achieved. Another object of the present invention is to provide a semiconductor device, a multilayered circuit board, and an electronic component which are manufactured by using the dicing-tape-integrated adhesive sheet and thus have high electrical connection reliability.

### Solution to Problem

The objects are accomplished by the following (1) to (20).

(1) A dicing-tape-integrated adhesive sheet which has a laminated structure including an adhesive film which has a first terminal of a support body and a second terminal of an adherend that are electrically connected using solder and by which the support body and the adherend are adhered to each other and a dicing tape, in which, when it is assumed that an adhesion temperature when the adhesive film is adhered to a surface on which the first terminal of the support body is formed is T[° C.], a pressure applied to the adhesive film is P[Pa], and a melt viscosity of the adhesive film at the adhesion temperature is η[Pa·s], a relationship of 1.2×10³≦(T×P)/η≦1.5×10⁹ is satisfied, and the adhesion temperature T is 60 to 150° C., the pressure P is 0.2 to 1.0 MPa, and the melt viscosity η of the adhesive film at the adhesion temperature T is 0.1 to 100,000 Pa·s.

(2) The dicing-tape-integrated adhesive sheet described in (1), in which an ambient pressure when the adhesive film is adhered to the surface on which the first terminal of the support body is formed is 100 kPa or less.

(3) The dicing-tape-integrated adhesive sheet described in (1) or (2), in which the adhesive film contains: (A) a phenol resin: (B) an epoxy resin; (C) a compound having a flux activity function; and (D) a film-forming resin.

(4) The dicing-tape-integrated adhesive sheet described in any of (1) to (3), in which the adhesive film contains 3 to 30 weight % of (A) the phenol resin, 10 to 80 weight % of (B) the epoxy resin, 1 to 30 weight % of (C) the compound having a flux activity function, and 1 to 50 weight % of (D) the film-forming resin.

(5) The dicing-tape-integrated adhesive sheet described in (3) or (4), in which (B) the epoxy resin is in a liquid phase at 25° C.

(6) The dicing-tape-integrated adhesive sheet described in any of (3) to (5), in which a viscosity of (B) the epoxy resin at 25° C. is 500 to 50,000 mPa·s.

(7) The dicing-tape-integrated adhesive sheet described in any of (3) to (6), in which a blending ratio ((B)/(C)) of (B) the epoxy resin and (C) the compound having a flux activity function is 0.5 to 12.0.

(8) The dicing-tape-integrated adhesive sheet described in any of (3) to (7), in which (C) the compound having a flux activity function is a compound having a flux activity function, which contains two phenolic hydroxyl groups in a molecule and at least one carboxyl group directly bonded to an aromatic group.

(9) The dicing-tape-integrated adhesive sheet described in any of (3) to (8), in which (D) the film-forming resin contains a phenoxy resin.

(10) The dicing-tape-integrated adhesive sheet described in any of (1) to (9), in which the adhesive film further contains a filling material.

(11) The dicing-tape-integrated adhesive sheet described in (10), in which a content of the filling material is 0.1 weight % or higher and 80 weight % or less.

(12) The dicing-tape-integrated adhesive sheet described in any of (1) to (11), in which the dicing tape includes an adhesive layer and a support film, and the adhesive film is laminated on the adhesive layer.

(13) The dicing-tape-integrated adhesive sheet described in (12), in which the adhesive layer is made of a photo-curable resin.

(14) The dicing-tape-integrated adhesive sheet described in any of (1) to (11), in which the dicing tape includes an adhesive layer and a support film, and the adhesive film is laminated on the adhesive layer via an interposition layer.

(15) The dicing-tape-integrated adhesive sheet described in (14), in which a tackiness of the adhesive layer of the dicing tape is higher than a tackiness of the interposition layer.

(16) The dicing-tape-integrated adhesive sheet described in (14) or (15), in which the interposition layer is made of a photo-curable resin.

(17) A semiconductor device including: a cured material of the adhesive film described in any of (1) to (16).

(18) A multilayered circuit board including: a cured material of the adhesive film described in any of (1) to (16).

(19) An electronic component including: a cured material of the adhesive film described in any of (1) to (16).

### Advantageous Effects of Invention

According to the present invention, a dicing-tape-integrated adhesive sheet in which connection between terminals of opposing members and encapsulating of voids between the members can be simultaneously performed, unevenness which occurs due to the plurality of wiring circuits and the like on the circuit board can be suitably buried, and thus excellent workability is achieved can be provided, and a semiconductor device, a multilayered circuit board, and an electronic component which are manufactured by using the dicing-tape-integrated adhesive sheet can be provided.

### BRIEF DESCRIPTION OF DRAWINGS

FIG. 1 is a cross-sectional view schematically illustrating an example of a method of manufacturing a dicing-tape-integrated adhesive sheet of the present invention.

FIG. 2 is a cross-sectional view schematically illustrating an example of a method of manufacturing a semiconductor device using the dicing-tape-integrated adhesive sheet of the present invention.

FIG. 3 is a cross-sectional view schematically illustrating an example of the method of manufacturing a semiconductor device using the dicing-tape-integrated adhesive sheet of the present invention.

### DESCRIPTION OF EMBODIMENTS

Hereinafter, a dicing-tape-integrated adhesive sheet, a semiconductor device, a multilayered circuit board, and an electronic component of the present invention will be described.

The dicing-tape-integrated adhesive sheet of the present invention is a dicing-tape-integrated adhesive sheet which has a laminated structure including an adhesive film which has a first terminal of a support body and a second terminal of an adherend that are electrically connected using solder and by which the support body and the adherend are adhered to each other and a dicing tape. When it is assumed that an adhesion temperature when the adhesive film is adhered to a surface on which the first terminal of the support body is formed is T[° C.], a pressure applied to the adhesive film is P[MPa], and a melt viscosity of the adhesive film at the adhesion temperature is η[Pa·s], a relationship of 1.2×10³≦(T×P)/η≦1.5×10⁹ is satisfied. The adhesion temperature T is 60 to 150° C., the pressure P is 0.2 to 1.0 MPa, and the melt viscosity η of the adhesive film at the adhesion temperature is 0.1 to 100,000 Pa·s.

In addition, the semiconductor device, the multilayered circuit board, and the electronic component of the present invention are obtained by electrically connecting the support body having the first terminal to the adherend having the second terminal using a cured material of the adhesive film and adhering the support body to the adherend.

Hereinafter, the dicing-tape-integrated adhesive sheet, the semiconductor device, the multilayered circuit board, and the electronic component of the present invention will be described in detail.

The dicing-tape-integrated adhesive sheet of the present invention includes, as essential components, the adhesive film which has the first terminal of the support body and the second terminal of the adherend that are electrically connected using the solder and by which the support body and the adherend are adhered to each other, and the dicing tape. In addition, an interposition layer or an outer layer, which will be described later may be provided. The configuration of each portion of the dicing-tape-integrated adhesive sheet will be described sequentially.

In addition, in the dicing-tape-integrated adhesive sheet of the present invention, only the adhesive film is the component of the semiconductor device. By combining the adhesive film with other members in the dicing-tape-integrated adhesive sheet, the dicing-tape-integrated adhesive sheet of the present invention has excellent workability.

### (Dicing Tape)

As the dicing tape, any dicing tape which is typically used can be used.

Specifically, examples of the constituent material of a support film of the dicing tape include polyethylene, polypropylene, polybutene, polybutadiene, polymethylpentene, polyvinyl chloride, a vinyl chloride copolymer, polyethylene terephthalate, polybutylene terephthalate, polyurethane, an ethylene-vinyl acetate copolymer, an ionomer, an ethylene-(meth)acrylic acid copolymer, an ethylene-(meth)acrylic acid ester copolymer, polystyrene, vinyl polyisoprene, polycarbonate, and polyolefin and include a mixture of one type or two or more types thereof.

The average thickness of the support film is not particularly limited, but is preferably about 5 to 200 μm and is more preferably about 30 to 150 μm. Accordingly, the support film has appropriate rigidity and thus reliably supports the dicing tape and the adhesive film and facilitates handling of the dicing-tape-integrated adhesive sheet. In addition, by appropriately bending the dicing-tape-integrated adhesive sheet, adhesion of the support film to the support body having the first terminal can be increased.

In addition, as an adhesive layer of the dicing tape, those made of a first resin composition containing an acrylic adhesive, a rubber-based adhesive, and the like can be used.

In addition, the constituent material of the support film is not particularly limited. However, in a case where the tackiness of the first resin composition is controlled by light (visible light, near-infrared light, and ultraviolet light), X-rays, electron rays, and the like, those that transmit light (visible light, near-infrared light, and ultraviolet light), X-rays, electron rays, and the like are preferable. For example, a polyolefin-based resin such as polyvinyl chloride, polyethylene, polypropylene, polybutene, polybutadiene, and polymethylpentene, an olefin-based copolymer such as an ethylene-vinyl acetate copolymer, an ionomer, an ethylene-(meth)acrylic acid copolymer, and an ethylene-(meth)acrylic acid ester copolymer, a polyalkylene terephthalate-based resin such as polyethylene terephthalate and polybutylene terephthalate, a thermoplastic resin such as a styrene-based thermoplastic elastomer, an olefin-based thermoplastic elastomer, polyvinyl isoprene, and polycarbonate, or a mixture of the thermoplastic resins are used.

Particularly, as the constituent material of the support film, a mixture of polypropylene and an elastomer or a mixture of polyethylene and an elastomer are preferably used. In addition, as the elastomer, a block copolymer made of a polystyrene segment expressed by General Formula (1) and a vinyl polyisoprene segment expressed by General Formula (2) is preferable. Using the materials as such, sufficient cushioning properties can be obtained when the dicing-tape-integrated adhesive sheet is adhered to the surface on which the first terminal of the support body is formed.

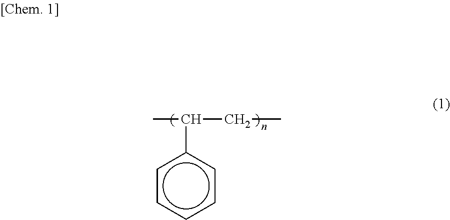

(In Formula (1), n is an integer of 2 or greater)

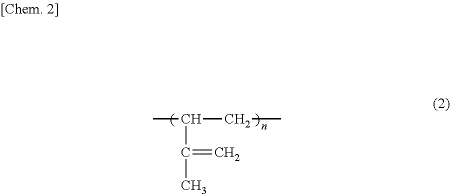

(in General Formula (2), n is an integer of 2 or greater)

A method of manufacturing the support film is not particularly limited, and a general molding method such as a calendar method and an extrusion molding method can be used. It is preferable that a functional group which reacts with a material included in the adhesive layer such as a hydroxyl group or an amino group be exposed to the surface of the support film. In addition, in order to increase the adhesion between the support film and the adhesive layer, it is preferable that the surface of the support film be subject to a surface treatment such as a corona treatment or anchor coating.

As the acrylic adhesive, for example, a resin made of a (meth)acrylic acid and an ester thereof, or a copolymer of a (meth)acrylic acid and an ester thereof and an unsaturated monomer (for example, vinyl acetate, styrene, or acrylonitrile) that is copolymerizable therewith is used. In addition, two or more types of the copolymer may be mixed.

Among these, a copolymer of one or more types selected from the group consisting of methyl (meth)acrylate, ethylhexyl (meth)acrylate, and butyl (meth)acrylate and one or more types selected from hydroxyethyl (meth)acrylate and vinyl acetate is preferable. Accordingly, adhesion or tackiness to an object (for example, the interposition layer, described later, and the support film, which will also be described later) to which the adhesive layer of the dicing tape is adhered is easily controlled.

In addition, in order to control the tackiness (adhesion), to the first resin composition, a monomer and an oligomer such as an isocyanate compound including urethane acrylate, an acrylate monomer, or a polyvalent isocyanate compound (for example, 2,4-tolylene diisocyanate and 2,6-tolylene diisocyanate), and the like may be added.

In addition, in a case where the tackiness of the adhesive layer is controlled by light (visible light, near-infrared light, and ultraviolet light), the first resin composition preferably includes a photo-curable component. The photo-curable component is cured by light irradiation, and an acrylic adhesive or the like is incorporated into a cross-linking structure of the curable component through curing. As a result, the tackiness of the adhesive layer is degraded. As the photo-curable component, for example, a low-molecular-weight compound including at least two or more polymerizable carbon-carbon double bonds capable of being three-dimensionally cross-linked by irradiation of energy rays such as ultraviolet light or electron rays in a molecule may be used.

Specifically, the photo-curable component is not particularly limited. For example, trimethylolpropane triacrylate, tetramethylolmethane tetraacrylate, pentaerythritol triacrylate, pentaerythritol tetraacrylate, dipentaerythritol monohydroxy pentaacrylate, dipentaerythritol hexaacrylate, 1,4-butylene glycol diacrylate, 1,6-hexanediol diacrylate, polyethylene glycol diacrylate, commercially available oligoester acrylate, aromatic or aliphatic urethane acrylate, and the like are used. Among these, urethane acrylate is preferable.

In addition, the photo-curable component is not particularly limited, and it is preferable that two or more photo-curable components having different weight-average molecular weights be mixed. This is because when the curable component as such is used, the degree of crosslinking of the resin is controlled through the light irradiation and releasability (=pickup property) can be enhanced. In addition, as the curable component, for example, a mixture of a first photo-curable component and a second photo-curable component having a greater weight-average molecular weight than that of the first photo-curable component may be used.

The effect of reducing the tackiness of the adhesive layer by the photo-curable component is not particularly limited. For example, light irradiation may be performed on the adhesive layer through the support film of the dicing tape after a dicing process to reduce the tackiness of the adhesive layer, thereby obtaining appropriate releasability (=pickup property).

The photo-curable component is not particularly limited, and it is preferable that 20 or higher parts by weight and 200 or less parts by weight thereof with respect to 100 parts by weight of an adhesive such as an acrylic adhesive be blended. By adjusting the blending amount of the photo-curable component, releasability (=pickup property) becomes more appropriate.

In addition, a photoinitiator which is the same type as the second resin composition, which will be described later, may be added to the first resin composition.

Further, in the case where the photo-curable component is included in the first resin composition, in order to accelerate photo-curing by light irradiation, the photoinitiator is preferably contained. By containing the photoinitiator, polymerization initiation of the photo-curable component can be facilitated. The photoinitiator is not particularly limited, and for example, 2,2-dimethoxy-1,2-diphenylethane-1-on, benzophenone, acetophenone, benzoin, benzoin methyl ether, benzoin ethyl ether, benzoin isopropyl ether, benzyl diphenyl sulfide, tetramethylthiuram monosulfide, azobisisobutyronitrile, dibenzyl, diacetyl, and β-chloro anthraquinone may be used.

In addition, the first resin composition may contain a crosslinking agent in order to control the tackiness of the adhesive layer. Examples of the crosslinking agent include an epoxy-based crosslinking agent, an isocyanate-based crosslinking agent, a methylol-based crosslinking agent, a chelate-based crosslinking agent, an aziridine-based crosslinking agent, a melamine-based crosslinking agent, and a polyvalent metal chelate-based crosslinking agent. Among these, the isocyanate-based crosslinking agent is preferable.

The isocyanate-based crosslinking agent is not particularly limited, and examples thereof include a polyisocyanate compound of a polyvalent isocyanate and a trimer of a polyisocyanate compound; a trimer of an isocyanate-terminated compound obtained by the reaction of a polyisocyanate compound and a polyol compound; and a blocked polyisocyanate compound in which an isocyanate-terminated urethane prepolymer is blocked by phenol, oxime, and the like.

As the polyvalent isocyanate, for example, 2,4-tolylene diisocyanate, 2,6-tolylene diisocyanate, 1,3-xylylene diisocyanate, 1,4-xylene diisocyanate, diphenylmethane-4,4′-diisocyanate, diphenylmethane-2,4′-diisocyanate, 3-methyl diphenylmethane diisocyanate, hexamethylene diisocyanate, isophorone diisocyanate, dicyclohexylmethane-4,4′-diisocyanate, and dicyclohexylmethane-2,4′-diisocyanate are used. Among these, the polyvalent isocyanate containing at least one type selected from the group consisting of 2,4-tolylene diisocyanate, diphenylmethane-4,4′-diisocyanate, and hexamethylene diisocyanate is preferable.

The content of the crosslinking agent is not particularly limited, and it is preferable that 5 or greater parts by weight and 50 or less parts by weight thereof with respect to 100 parts by weight of the acrylic adhesive be blended. By adjusting the blending amount of the crosslinking agent, releasability (=pickup property) of the dicing tape become more appropriate.

In addition, for the purpose of increasing adhesion strength and shear strength, a tackifier such as a rosin resin, a terpene resin, a coumarone resin, a phenol resin, a styrene resin, an aliphatic petroleum resin, an aromatic petroleum resin, or an aliphatic aromatic petroleum resin, and the like may be added.

The average thickness of the adhesive layer of the dicing tape is not particularly limited, and is preferably about 1 to 100 μm and is more preferably about 3 to 20 μm. When the average thickness of the adhesive layer of the dicing tape is in the above range, shape followability of the adhesive layer of the dicing tape is ensured, and thus the adhesion of the adhesive film to a semiconductor wafer can be further increased.

Although the interposition layer will be described later, the dicing-tape-integrated adhesive sheet may include the interposition layer between the adhesive layer of the dicing tape and the adhesive film. In this case, the adhesive layer of the dicing tape preferably has higher tackiness than that of the interposition layer. Accordingly, the adhesion of the adhesive layer of the dicing tape to the interposition layer and the support film becomes greater than the adhesion of the interposition layer to the adhesive film. Therefore, in a pick-up process in the manufacture of the semiconductor device, which will be described later, peeling occurs at a desired interface (that is, the interface between the interposition layer and the adhesive film) at which peeling has to occur.

In addition, by increasing the tackiness of the adhesive layer of the dicing tape, in a second process of the manufacture of the semiconductor device, which will be described later, when the semiconductor wafer is diced to be divided, the dicing tape and a wafer ring are reliably fixed to each other. As a result, a positional shift of the semiconductor wafer is reliably prevented, and thus the dimensional accuracy of a semiconductor chip can be increased.

### (Adhesive Film)

The adhesive film included in the dicing-film-integrated adhesive sheet of the present invention is a film having adhesion, is used when a semiconductor chip or a semiconductor package is mounted on a circuit board, and is caused to stick to the semiconductor chip or the semiconductor package, and a circuit board. In addition, the adhesive film has a flux activity function. In addition, in this specification, the circuit board is referred to as, for example, a semiconductor chip, a semiconductor wafer, a rigid board, a flexible board, or a rigid flexible substrate, in which a wiring circuit is formed.

The adhesive film used for such applications in the related art has a problem in that when the adhesive film is adhered to the circuit board, unevenness (gap) which occurs due to a plurality of wiring circuits and the like on the circuit board cannot be sufficiently buried, a void occurs between the adhesive film and the circuit board, and a failure of the adhesion between the semiconductor chip and the like and the circuit board occurs.

For this, in the present invention, under the condition in which an adhesion temperature T when the adhesive film and the circuit board are adhered to each other is 60 to 150° C., a pressure P applied to the adhesive film is 0.2 to 1.0 MPa, and a melt viscosity η of the adhesive film at the adhesion temperature T[° C.] is 0.1 to 100,000 Pa·s, the adhesion temperature T[° C.], the pressure P[Pa], and the melt viscosity η[Pa·s] satisfy a relationship of 1.2×10³≦(T×P)/η≦0.5×10⁹.

Due to such characteristics, when the adhesive film and the circuit board are adhered to each other, the unevenness (gap) which occurs due to the plurality of wiring circuits and the like on the circuit board can be suitably buried with the adhesive film, and thus the occurrence of voids between the adhesive film and the circuit board can be effectively prevented. For this, when the value of (T×P)/η is less than the lower limit, a void occurs between the adhesive film and the circuit board. In addition, the unevenness of the wiring circuit and the like becomes the unevenness of the surface of the adhesive film, and thus the adhesion to the semiconductor chip and the like is degraded. On the other hand, when the value of (T×P)/η is higher than the upper limit, the adhesive film becomes too soft, and thus the adhesive film protrudes from an edge portion of the circuit board.

In addition, since such characteristics are provided, physical properties such as adhesion of the interface between the adhesive film and a dicing sheet or between the adhesive film and the interposition layer are enhanced, and thus enhanced workability can be realized. That is, by allowing the value of (T×P)/η to be the lower limit or higher, the adhesion between the adhesive film and the dicing sheet or between the adhesive film and the interposition layer becomes sufficient, and the adhesive film can be prevented from unintentionally peeling in the dicing process and the like. In addition, by allowing the value of (T×P)/η to be the upper limit or less, defects caused from the transfer and the like of the adhesive layer and the like to the surface of the adhesive film due to strong adhesion between the adhesive film and the dicing sheet or between the adhesive film and the interposition layer can be effectively suppressed.

In this manner, in the adhesive film of the present invention, under the condition described above, the adhesion temperature T[° C.], the pressure P[Pa], and the melt viscosity η[Pa·s] satisfy the relationship of 1.2×10³≦(T×P)/η≦1.5×10⁹, but preferably satisfy a relationship of 1.6×10³≦(T×P)/η≦1.3×10⁹, and more preferably satisfy a relationship of 2.0×10³≦(T×P)/η≦1.0×10⁹. Accordingly, the effect of the present invention may become more apparent.

In addition, the melt viscosity η of the adhesive film at the adhesion temperature T[° C.] of the adhesive film of the present invention is 0.1 to 100,000 Pa·s. Accordingly, when the adhesive film and the circuit board are adhered to each other, the unevenness (gap) which occurs due to the plurality of wiring circuits and the like on the circuit board can be more suitably buried with the adhesive film.

By allowing the melt viscosity to be 0.1 Pa·s or more, the melted adhesive film can be prevented from creeping up and contaminating the support body or the adherend. In addition, by allowing the melt viscosity to be 100,000 Pa·s or less, the adhesive film melted between the opposing terminals can be prevented from being bitten and causing conduction failure.

The melt viscosity is preferably 0.2 Pa·s or higher, and particularly preferably 0.5 Pa·s or higher. Accordingly, the adhesive film melted can be more effectively prevented from creeping up and contaminating the support body or the adherend. In addition, the melt viscosity is preferably 70,000 Pa·s or less, and particularly preferably 30,000 Pa·s or less. Accordingly, the adhesive film melted between the opposing terminals can be more effectively prevented from being bitten and causing conduction failure.

In addition, by allowing the melt viscosity to be 0.1 Pa·s or higher, defects occurring from the transfer and the like of the adhesive layer and the like to the surface of the adhesive film due to strong adhesion between the adhesive film and the dicing sheet or between the adhesive film and the interposition layer can be effectively suppressed. In addition, by allowing the melt viscosity to be 100,000 Pa·s or less, the adhesion between the adhesive film and the dicing sheet or between the adhesive film and the interposition layer becomes sufficient, and the adhesive film can be prevented from unintentionally peeling in the dicing process and the like.

Here, the melt viscosity η of the adhesive film is obtained by the following measurement method.

The adhesive film having a thickness of 100 pin was measured under the condition of a parallel plate of 20 mmφ, a gap of 0.05 mm, a frequency 0.1 Hz, and a rate of temperature increase of 10° C./min using a viscoelasticity measuring apparatus (RheoStress RS150 manufactured by HAAKE Co. Ltd.), and a value at the adhesion temperature of the adhesive film was measured as a measurement value.

The adhesive film as such may include, for example, the following components.

The adhesive film of the present invention preferably includes (A) a phenol resin (hereinafter, referred to as a compound (A)), (B) an epoxy resin (hereinafter, referred to as a compound (B)), (C) a compound having a flux activity function (hereinafter, referred to as a compound (C)), and (D) a film-forming resin (hereinafter, referred to as a compound (D)).

Accordingly, the adhesive film which satisfies the relationships described above can be more easily obtained, and thus when the adhesive film and the circuit board are adhered to each other, the unevenness (gap) which occurs due to the plurality of wiring circuits and the like on the circuit board can be more effectively buried with the adhesive film.

In addition, the adhesive film preferably contains 3 to 30 weight % of the compound (A), 10 to 80 weight % of the compound (B), 1 to 30 weight % of the compound (C), and 1 to 50 weight % of the compound (D). By applying the blending amounts, the melt viscosity 11 at the adhesion temperature of the adhesive film may be allowed to be 0.1 to 100,000 Pa·s. Moreover, it is preferable that 3 to 28 weight % of the compound (A), 12 to 78 weight % of the compound (B), 3 to 25 weight % of the compound (C), and 6 to 40 weight % of the compound (D) be contained, and it is most preferable that 5 to 25 weight % of the compound (A), 15 to 75 weight % of the compound (B), 3 to 20 weight % of the compound (C), and 10 to 35 weight % of the compound (D) be contained. Accordingly, the adhesive film which satisfies the relationships described above can be more easily obtained.

Since the adhesive film contains the compound (A), a glass-transition temperature of the cured material of the adhesive film can be increased, and an ion migration resistance can be increased. In addition, appropriate flexibility can be imparted to the adhesive film, and thus brittleness of the adhesive film can be improved. Furthermore, appropriate tackiness can be imparted to the adhesive film, and thus the adhesive film having excellent workability can be obtained.

The compound (A) is not particularly limited, and examples thereof include a phenol novolac resin, a cresol novolac resin, a bisphenol A type novolac resin, a bisphenol F type novolac resin, a bisphenol AF type novolac resin, an alkylphenol novolac resin, a biphenol novolac resin, a naphthol novolac resin, a resorcinol novolac resin, a biphenylaralkyl type phenol resin, a naphthol aralkyl resin, a dicyclopentadiene type phenol resins, a polyfunctional phenol resin, a trisphenylmethane type phenol resin, a Zilog type phenol resin, and a Zilog type naphthol resin. Among these, the phenol novolac resin and the cresol novolac resin which can easily satisfy the relationships described above and can effectively increase a glass-transition temperature of the cured material of the adhesive film are preferably used.

The content of the compound (A) in the adhesive film is not particularly limited, and is preferably 3 to 30 weight %, more preferably 3 to 28 weight %, and even more preferably 5 to 25 weight %. By allowing the content of the compound (A) to be in the above range, the adhesive film which satisfies the relationships described above can be more easily obtained, and when the adhesive film and the circuit board are adhered to each other, the unevenness (gap) which occurs due to the plurality of wiring circuits and the like on the circuit board can be more effectively buried with the adhesive film. In addition, the glass-transition temperature of the cured material of the adhesive film can be effectively increased.

The weight-average molecular weight of the compound (A) is not particularly limited, and is preferably 300 to 1,500, and particularly preferably 400 to 1,400. Accordingly, gas released when the adhesive film is cured can more effectively be prevented from increasing in amount and contaminating the surfaces of the semiconductor chip and the support body or the adherend of the circuit board. Accordingly, flexibility and bending properties of the adhesive film can be more effectively ensured. Here, the weight-average molecular weight may be measured by GPC (Gel Permeation Chromatography).

In addition, since the adhesive film contains the (B) the epoxy resin, the adhesive film which satisfies the relationships described above can be more easily obtained, and when the adhesive film and the circuit board are adhered to each other, the unevenness (gap) which occurs due to the plurality of wiring circuits and the like on the circuit board can be more effectively buried with the adhesive film. Accordingly, flexibility and bending properties can be imparted to the adhesive film, and thus the adhesive film having excellent handleability can be obtained.

Examples of the compound (B) include a bisphenol A type epoxy resin, a bisphenol F type epoxy resin, a glycidyl amine type epoxy resin, a glycidyl ester type epoxy resin, a naphthalene type epoxy resin, an allyl bisphenol A type epoxy resin, a bisphenol S type epoxy resin, a phenol novolac type epoxy resin, a cresol novolac type epoxy resin, a glycidyl ester type epoxy resin, a trifunctional epoxy resin, and a tetrafunctional epoxy resin. Among these, the bisphenol A type epoxy resin and the bisphenol F type epoxy resin by which the adhesive film that satisfies the relationships described above can be more easily obtained and which has excellent adhesion of the adhesive film to the semiconductor chip or the support body or the adherend and further has excellent mechanical properties after curing the adhesive film are preferable.

In addition, it is preferable that the epoxy resin as the compound (B) be in a liquid phase at 25° C. The viscosity thereof at 25° C. is more preferably 500 to 50,000 mPa·s, and is even more preferably 800 to 40,000 mPa·s. By allowing the viscosity at 25° C. to be the lower limit or higher, the tackiness of the adhesive film becomes strong, and thus degradation in the handleability can be prevented. In addition, by allowing the viscosity at 25° C. to be the upper limit or less, the flexibility and the bending properties of the adhesive film can be ensured. In addition, by using the epoxy resin having such a viscosity, the adhesive film which satisfies the relationships described above can be more easily obtained.

The content of the epoxy resin as the compound (B) is not particularly limited, and is preferably 10 to 80 weight %, more preferably 12 to 78 weight %, and even more preferably 15 to 75 weight %. Accordingly, the flexibility and the bending properties of the adhesive film can be more effectively exhibited. In addition, accordingly, the tackiness of the adhesive film becomes strong, and thus degradation in the handleability can be more effectively prevented.

In addition, since the adhesive film contains (C) the compound having a flux activity function, a metal oxide film of a solder surface of at least one of the first terminal of the support body (the semiconductor chip, the board, and the like) and the second terminal of the adherend (the semiconductor chip, the board, and the like) can be removed, and the first terminal and the second terminal can be reliably soldered. Therefore, the multilayered circuit board, the electronic component, the semiconductor device, and the like having high connection reliability can be obtained.

The compound (C) is not particularly limited as long as it has a function of removing the metal oxide film of the solder surface, and is preferably a compound which has any of a carboxyl group and a phenolic hydroxyl group or both the carboxyl group and the phenolic hydroxyl group.

The blending amount of the compound (C) is preferably 1 to 30 weight %, more preferably 3 to 25 weight % of the compound (C), and most preferably 3 to 20 weight %. By allowing the blending amount of the compound (C) to be in the above range, flux activity can be improved, the compound (A), the compound (B), and the compound (C) which do not react when the adhesive film is cured can be prevented from remaining, thereby improving migration resistance.

In addition, among the compounds which act as a curing agent of the epoxy resin, (C) the compound having the flux activity function (hereinafter, such a compound is described as the curing agent having the flux activity function) is present. For example, an aliphatic dicarboxylic acid, an aromatic dicarboxylic acid, and the like which act as the curing agent of the epoxy resin also have a flux action. In the present invention, the curing agent having the flux activity function, which acts as a flux and acts as the curing agent of the epoxy resin, can be appropriately used.

In addition, (C) the compound having the flux activity function, which has the carboxyl group, is referred to as a compound which has one or more carboxyl groups in a molecule, and may be in a liquid phase or a solid. In addition, (C) the compound having the flux activity function, which has the phenolic hydroxyl group, is referred to as a compound which has one or more phenolic hydroxyl groups in a molecule, and may be in a liquid phase or a solid. In addition, (C) the compound having the flux activity function, which has the carboxyl group and the phenolic hydroxyl group, is referred to as a compound which has one or more carboxyl groups and one or more phenolic hydroxyl groups in a molecule, and may be in a liquid phase or a solid.

Among these, as (C) the compound having the flux activity function, which has the carboxyl group, there are aliphatic acid anhydride, alicyclic acid anhydride, aromatic acid anhydride, aliphatic carboxylic acid, aromatic carboxylic acid, and the like.

As the aliphatic acid anhydride associated with (C) the compound having the flux activity function, which has the carboxyl group, there are succinic anhydride, polyadipic acid anhydride, polyazelaic acid anhydride, polysebacic acid anhydride, and the like.

As the alicyclic acid anhydride associated with (C) the compound having the flux activity function, which has the carboxyl group, there are methyltetrahydrophthalic acid anhydride, methylhexahydrophthalic acid anhydride, methyl himic acid anhydride, hexahydrophthalic acid anhydride, tetrahydrophthalic acid anhydride, trialkyltetrahydrophtalic acid anhydride, methylcyclohexene dicarboxylic acid anhydride, and the like.

As the aromatic acid anhydride associated with (C) the compound having the flux activity function, which has the carboxyl group, there are phthalic acid anhydride, trimellitic acid anhydride, pyromellitic acid anhydride, benzophenonetetracarboxylic acid anhydride, ethylene glycol bistrimellitate, glycerol tristrimellitate, and the like.

Examples of the aliphatic carboxylic acid associated with (C) the compound having the flux activity function, which has the carboxyl group, include a compound expressed in General Formula (3), formic acid, acetic acid, propionic acid, butyric acid, valeric acid, pivalic acid, caproic acid, caprylic acid, lauric acid, myristic acid, palmitic acid, stearic acid, acrylic acid, methacrylic acid, crotonic acid, oleic acid, fumaric acid, maleic acid, oxalic acid, malonic acid, and succinic acid.

HOOC—(CH₂)ₙ—COOH (3)

(in General Formula (3), n represents an integer of 1 or higher and 20 or less)

As the aromatic carboxylic acid associated with (C) the compound having the flux activity function, which has the carboxyl group, there are benzoic acid, phthalic acid, isophthalic acid, terephthalic acid, hemimellitic acid, trimellitic acid, trimesic acid, mellophanic acid, prehnitic acid, pyromellitic acid, mellitic acid, xylic acid, hemellitic acid, mesitylene acid, prehnitylic acid, toluic acid, cinnamic acid, salicylic acid, 2,3-dihydroxybenzoic acid, 2,4-dihydroxybenzoic acid, gentisic acid (2,5-dihydroxybenzoic acid), 2,6-dihydroxybenzoic acid, 3,5-dihydroxybenzoic acid, gallic acid (3,4,5-trihydroxybenzoic acid), naphthoic acid derivatives such as 1,4-dihydroxy-2-naphthoic acid and 3,5-dihydroxy-2-naphthoic acid, phenolphthalin, diphenolic acid, and the like.

Among (C) the compounds having the flux activity function, which has the carboxyl group, in terms of the good balance between the activity of (C) the compound having the flux activity function, the amount of gas released during the curing of the adhesive film, and the elastic modulus, glass-transition temperature, or the like of the adhesive film after the curing, the compound expressed in General Formula (3) is preferable. In addition, among the compounds expressed in General Formula (3), compounds in which n is 3 to 10 in General Formula (3) are particularly preferable because an increase in the elastic modulus of the adhesive film 1 after the curing can be suppressed and the adhesion between the support body such as the semiconductor chip, the board, and the like and the adherend can be improved.

Among the compounds expressed in General Formula (3), examples of the compounds in which n is 3 to 10 in General Formula (3) include a glutaric acid (HOOC—(CH₂)₃—COOH) of n=3, an adipic acid (HOOC—(CH₂)₄—COOH) of n=4, a pimnelic acid (HOOC—(CH₂)₅—COOH) of n=5, a sebacic acid (HOOC—(CH₂)₈—COOH) of n=8, and HOOC—(CH₂)₁₀—COOH of n=10.

As (C) the compound having the flux activity function which has the phenolic hydroxyl group, phenols are employed, and specific examples thereof include monomers which contain a phenolic hydroxyl group such as phenol, o-cresol, 2,6-xylenol, p-cresol, m-cresol, o-ethylphenol, 2,4-xylenol, 2,5xylenol, m-ethylphenol, 2,3-xylenol, mesitol, 3,5-xylenol, p-tertiary butylphenol, catechol, p-tertiary amyl phenol, resorcinol, p-octylphenol, p-phenylphenol, bisphenol A, bisphenol F, bisphenol AF, biphenol, diallyl bisphenol F, diallyl bisphenol A, trisphenol, and tetrakisphenol.

The compound which has either of the carboxyl group and the phenolic hydroxyl group or both the carboxyl group and the phenolic hydroxyl group is three-dimensionally incorporated by the reaction with the epoxy resin.

Therefore, from the viewpoint of improvement in the formation of a three-dimensional network of the epoxy resin after the curing, as (C) the compound having the flux activity function, the curing agent which has the flux action and flux activity to act as the curing agent of the epoxy resin is preferably used. Examples of the curing agent which has the flux activity include the compound which has, in a molecule, two or more phenolic hydroxyl groups which can be added to the epoxy resin and one or more carboxyl groups which are directly bonded to aromatic series that exhibits the flux function (reduction). As the curing agent which has the flux activity as such, benzoic acid derivatives such as 2,3-dihydroxybenzoic acid, 2,4-dihydroxybenzoic acid, gentisic acid (2,5-dihydroxybenzoic acid), 2,6-dihydroxybenzoic acid, 3,4-dihydroxybenzoic acid, and gallic acid (3,4,5-trihydroxybenzoic acid); naphthoic acid derivatives such as 1,4-dihydroxy-2-naphthoic acid, 3,5-dihydroxy-2-naphthoic acid, and 3,7-dihydroxy-2-naphthoic acid; phenolphthalein; diphenolic acid; and the like are employed. They may be used singly or in a combination of two or more types thereof.

Among these, the 2,3-dihydroxybenzoic acid, the gentisic acid, and the phenolphthalin in which an effect of removing the metal oxide film of the solder surface and reactivity with the epoxy resin are excellent are preferably used.

In addition, the blending amount of the curing agent which has the flux activity in the adhesive film is preferably 1 to 30 weight %, more preferably 3 to 25 weight %, and particularly preferably 3 to 20 weight %. By allowing the blending amount of the curing agent which has the flux activity in the adhesive film to be in the above range, the flux activity of the adhesive film can be improved, and the epoxy resin and the unreacted curing agent having the flux activity can be prevented from remaining in the adhesive film. In addition, when the unreacted curing agent having the flux activity remains, migration occurs.

The blending ratio of the compound (B) and the compound (C) is not particularly limited, and ((B)/(C)) is preferably 0.5 to 12.0, and particularly preferably 2.0 to 10.0. By allowing the ((B)/(C)) to be equal to or higher than the lower limit, the unreacted compound (C) can be reduced during the curing of the adhesive film, and thus migration resistance can be improved. In addition, by allowing the ((B)/(C)) to be equal to or lower than the upper limit, the unreacted compound (B) can be reduced during the curing of the adhesive film, and thus migration resistance can be improved.

In addition, since the adhesive film contains (D) the film-forming resin which improves film-forming properties of the adhesive film, a film state can be easily achieved. In addition, mechanical properties of the adhesive film are also excellent.

Examples of (D) the film-forming resin include a (meth)acrylic resin, a phenoxy resin, a polyester resin, a polyurethane resin, a polyimide resin, a siloxane-modified polyimide resin, polybutadiene, polypropylene, a styrene-butadiene-styrene copolymer, a styrene-ethylene-butylene-styrene copolymer, a polyacetal resin, a polyvinyl butyral resin, a polyvinyl acetal resin, a butyl rubber, a chloroprene rubber, a polyamide resin, a acrylonitrile-butadiene copolymer, a acrylonitrile-butadiene-acrylate copolymer, a acrylonitrile-butadiene-styrene copolymer, polyvinyl acetate, and nylon. They may be used singly or in a combination of two or more types thereof. Among these, as (D) the film-forming resin, at least one type selected from the group consisting of the (meth)acrylic resin, the phenoxy resin, and the polyimide resin is preferably used.

The weight-average molecular weight of (D) the film-forming resin is not particularly limited, and is preferably 10,000 or higher, more preferably 20,000 to 1,000,000, and even more preferably 30,000 to 900,000. By allowing the weight-average molecular weight to be in the above range, the film-forming properties of the adhesive film can be improved.

The content of (D) the film-forming resin is not particularly limited, and in the adhesive film, is preferably 1 to 50 weight %, more preferably 5 to 40 weight %, even more preferably 6 to 40 weight %, and most preferably 10 to 35 weight %. By allowing the content to be in the above range, fluidity of the adhesive film can be suppressed, and thus the adhesive film is easily handled.

In addition, the adhesive film may further contain a curing accelerator. The curing accelerator may be appropriately selected depending on the type of a curable resin and the like. As the curing accelerator, for example, an imidazole compound which has a melting point of 150° C. or higher may be used. When the melting point of the curing accelerator used is 150° C. or higher, before the curing of the adhesive film is completed, a solder component included in a solder bump can be moved to the surface of an inner electrode provided in the semiconductor chip, and thus good electrical connection between the inner electrodes can be achieved. As the imidazole compound which has a melting point of 150° C. or higher, 2-phenyl-4-methylimidazole, 2-phenyl hydroxy imidazole, 2-phenyl-4-methyl hydroxy imidazole, and the like may be employed, and they may be used singly or in a combination of two or more types thereof.

The content of the curing accelerator in the adhesive film is not particularly limited, and is preferably 0.005 to 10 weight %, and more preferably 0.01 to 5 weight %. Accordingly, the function as the curing accelerator is more effectively exhibited, curability of the adhesive film can be improved, and a good soldering structure can be obtained without an excessive increase in melt viscosity of the resin at the melting temperature of the solder component included in the solder bump. In addition, preservability of the adhesive film can be further improved.

The curing accelerators may be used singly or in a combination of two or more types thereof.

In addition, the adhesive film may further contain a silane coupling agent. By containing the silane coupling agent, the adhesion of the adhesive film to the support body such as the semiconductor chip or the board or the adherend can be increased. As the silane coupling agent, for example, an epoxy silane coupling agent, an aromatic series-containing amino silane coupling agent, and the like may be used. They may be used singly or in a combination of two or more types thereof. The blending amount of the silane coupling agent may be appropriately selected, and with respect to the entire resin compositions included in the adhesive film, is preferably 0.01 to 10 weight %, more preferably 0.05 to 5 weight %, and even more preferably 0.1 to 2 weight %.

The adhesive film may further contain an inorganic filling material. Accordingly, the coefficient of linear expansion of the adhesive film can be reduced, and accordingly reliability can be improved.

Examples of the inorganic filling material include silver, titanium oxide, silica, and mica, and among these, silica is preferable. In addition, as the shape of the silica filler, there are crushed silica and spherical silica, and the spherical silica is preferable.

The average particle diameter of the inorganic filling material is not particularly limited, and is preferably 0.01 μm or higher and 20 μm or less, and more preferably 0.05 μm or higher and 5 μm or less. By allowing the average particle diameter to be in the above range, aggregation of the inorganic filler in the adhesive film is suppressed, and thus the external appearance can be improved.

The content of the inorganic filling material is not particularly limited, and with respect to the entire resin compositions included in the adhesive film, is preferably 0.1 to 80 weight %, more preferably 5 to 75 weight %, and most preferably 20 to 70 weight %. By allowing the content to be in the above range, the difference in the coefficient of linear expansion between the adhesive film and the adherend after the curing is reduced, and thus stress generated during thermal shock can be reduced, thereby further suppressing peeling of the adherend. Moreover, an excessive increase in the elastic modulus of the adhesive film after the curing can be suppressed, and thus the reliability of the semiconductor device is increased.

The adhesive film can be obtained by applying a varnish obtained by mixing the resin components described above in a solvent onto a base material (support film) which is subjected to a peeling treatment such as a polyester sheet and drying the resultant at a predetermined temperature until the solvent is not practically included. The solvent used here is not particularly limited as long as it is inert with the components being used, and ketones such as acetone, methyl ethyl ketone, methyl isobutyl ketone, DIBK (diisobutyl ketone), cyclohexanone, and DAA(diaceton alcohol), aromatic hydrocarbons such as benzene, xylene, and toluene, alcohols such as methyl alcohol, ethyl alcohol, isopropyl alcohol, and n-butyl alcohol, cellosolves such as methyl cellosolve, ethyl cellosolve, butyl cellosolve, methyl cellosolve acetate, and ethyl cellosolve acetate, NMP (N-methyl-2-pyrrolidone), THF (tetrahydrofuran), DMF (dimethylformamide), DBE (dibasic acid ester), EEP (ethyl 3-ethoxypropionate), DMC (dimethyl carbonate), and the like are appropriately used. The amount of the solvent used is preferably in a range in which the solid content of the components mixed in the solvent is 10 to 60 weight %.

The thickness of the obtained adhesive film is not particularly limited, and is preferably 1 to 300 μm, and more preferably 5 to 200 μm. By allowing the thickness to be in the above range, a gap between bonding portions can be sufficiently filled with the resin component, and mechanical adhesion strength after curing the resin component can be ensured.

With the adhesive film obtained in this manner, when the adhesive film and the circuit board are adhered to each other, unevenness (gap) which occurs due to the plurality of wiring circuits and the like that are present on the adhesion surface of the circuit board can be suitably buried, and thus the occurrence of voids between the adhesive film and the circuit board can be more effectively prevented. Accordingly, the adhesive film can be appropriately used for connection between members which need soldering such as a semiconductor chip and a board, a board and a board, a semiconductor chip and a semiconductor chip, a semiconductor wafer and a semiconductor wafer, and the like.

In addition, the dicing-tape-integrated adhesive sheet of the present invention may be provided with one or more interposition layers in addition to the adhesive film and the dicing tape, and the following base material film, resin layer, or the like is employed as the interposition layer. In addition, one or more outer layers may be provided in one surface or both surfaces of the dicing-tape-integrated adhesive sheet, and the following base material film is employed as the outer layer. By providing the outer layer, a function as a protection film for protection from contamination or shock is achieved.

### (Base Material Film)

Examples of constituent materials of the base material film include polyethylene, polypropylene, polybutene, polybutadiene, polymethylpentene, polyvinyl chloride, vinyl chloride copolymer, polyethylene terephthalate, polybutylene terephthalate, polyurethane, an ethylene-vinyl acetate copolymer, an ionomer, an ethylene-(meth)acrylic acid copolymer, an ethylene-(meth)acrylic acid ester copolymer, polystyrene, vinyl polyisoprene, polycarbonate, polyolefin, and the like, and one type thereof or a combination of two or more types thereof may be employed.

The average thickness of the base material film is not particularly limited, and is preferably 5 to 200 μm, and more preferably 10 to 150 μm. Accordingly, the base material film has appropriate rigidity and thus reliably supports the dicing tape and the adhesive film and facilitates the handling of the dicing-tape-integrated adhesive sheet.

### (Resin Layer)

The resin layer is made of a general adhesive, and specifically, is made of the second resin composition which contains the acrylic adhesive, the rubber-based adhesive, and the like.

Examples of the acrylic adhesive include a resin made of a (meth)acrylic acid and an ester thereof, a copolymer of (meth)acrylic acid and an ester thereof and an unsaturated monomer (for example, vinyl acetate, styrene, or acrylonitrile) that is copolymerizable therewith, and the like. In addition, two or more types of the resins may be mixed.

Among these, a copolymer of one or more types selected from the group consisting of methyl (meth)acrylate, ethylhexyl (meth)acrylate, and butyl (meth)acrylate and one or more types selected from hydroxyethyl (meth)acrylate and vinyl acetate is preferable. Accordingly, adhesion or tackiness to the adherend (for example, the adhesive layer of the dicing tape, the adhesive film, and the like) which comes into contact with the resin layer is easily controlled.

In addition, in order to control the tackiness (adhesion), to the second resin composition, a monomer and an oligomer such as an isocyanate compound including urethane acrylate, an acrylate monomer, or a polyvalent isocyanate compound (for example, 2,4-tolylene diisocyanate and 2,6-tolylene diisocyanate), and the like may be added.

Furthermore, in a case where the resin layer is cured by ultraviolet light or the like, to the second resin composition, as the photoinitiator, an acetophenone-based compound such as methoxy acetophenone, 2,2-dimethoxy-2-phenylacetophenone, 2,2-diethoxyacetophenone, and 2-methyl-1-[4-(methylthio)-phenyl]-2-morpholinopropane-1, a benzophenone based compound, a benzoin-based compound, a benzoin isobutyl ether-based compound, a benzoin methyl benzoate-based compound, a benzoin benzoic acid-based compound, a benzoin methyl ether-based compound, a benzyl phenyl sulfide-based compound, a benzyl-based compound, a dibenzyl-based compound, a diacetyl-based compound, and the like may be added.

In addition, for the purpose of increasing adhesion strength and shear strength, to the second resin composition, a tackifier such as a rosin resin, a terpene resin, a coumarone resin, a phenol resin, a styrene resin, an aliphatic petroleum resin, an aromatic petroleum resin, or an aliphatic aromatic petroleum resin, and the like may be added.

The average thickness of the adhesive layer is not particularly limited, and is preferably about 1 to 100 μm and is more preferably about 3 to 50 μm. When the thickness is in the above range, particularly, peeling does not occur during dicing, peeling relatively easily occur during picking-up due to tensile load, deformation is less likely to occur during dicing or picking-up, and thus layers having excellent dicing properties and releasability (=pickup property) can be obtained.

### (Method of Manufacturing Dicing-Tape-Integrated Adhesive Sheet)

An embodiment of the dicing-tape-integrated adhesive sheet 10 described above will be described in detail as follows.

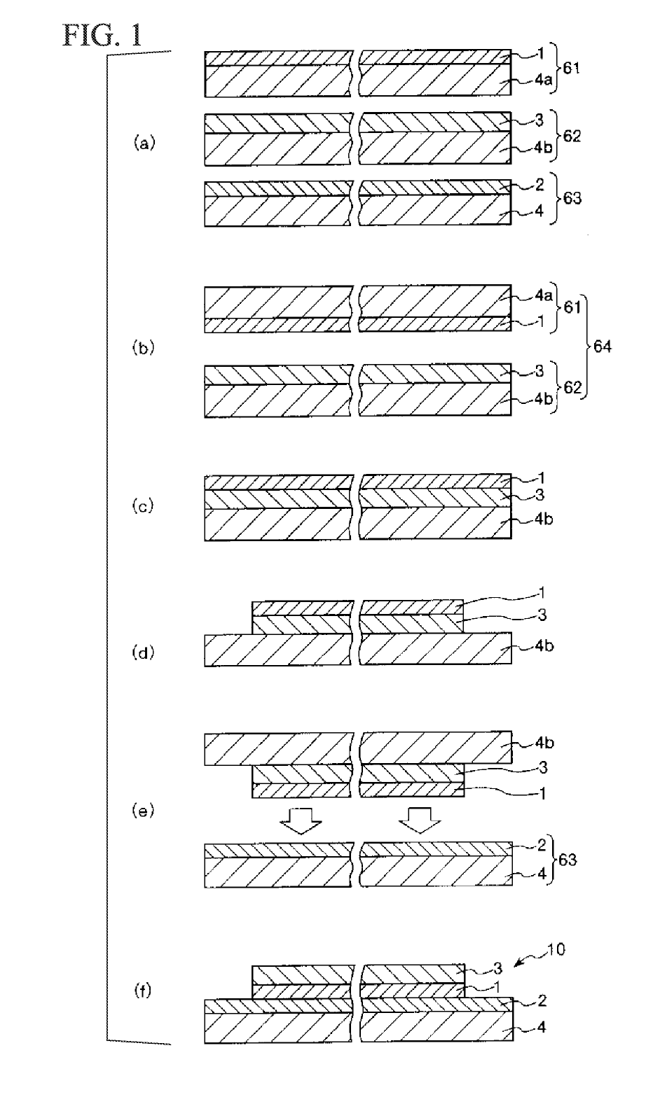

First, a base material 4a illustrated in FIG. 1(a) is prepared, and an interposition layer 1 is formed on one surface of the base material 4a. Accordingly, a laminate 61 of the base material 4a and the interposition layer 1 is obtained. The formation of the interposition layer 1 may be performed by a method of applying a resin varnish including the above-mentioned second resin composition using various application methods and drying the applied film, a method of laminating a film made of the second resin composition, or the like. In addition, the applied film may be cured by being irradiated with radiation such as ultraviolet rays.

Examples of the application method include a knife coating method, a roll coating method, a spray coating method, a gravure coating method, a bar coating method, and a curtain coating method.

In addition, in the same manner as the laminate 61, as illustrated in FIG. 1(a), an adhesive film 3 is formed on one surface of a prepared base material 4b, and a laminate 62 of the base material 4b and the adhesive film 3 is obtained.

Furthermore, in the same manner as each of the laminates 61 and 62, as illustrated in FIG. 1(a), an adhesive layer of the dicing tape 2 is formed on one surface of a prepared support film 4, and a laminate (dicing tape) 63 of the support film 4 and the adhesive layer of the dicing tape 2 is obtained.

Subsequently, as illustrated in FIG. 1(b), the laminate 61 and the laminate 62 are laminated so that the interposition layer 1 and the adhesive film 3 come into contact with each other, thereby obtaining a laminate 64. The lamination can be performed by, for example, a roll lamination method.

Subsequently, as illustrated in FIG. 1(c), the base material 4a is peeled away from the laminate 64. In addition, as illustrated in FIG. 1(d), in the laminate 64 from which the base material 4a is peeled away, outside parts of an effective region of the adhesive film 3 and the interposition layer 1 are removed so that the base material 4b remains. Here, the effective region indicates a region of which the outer periphery is much smaller than the outside diameter of a semiconductor wafer 7 or larger than the outside diameter and is smaller than the inside diameter of a wafer ring 9.

Subsequently, as illustrated in FIG. 1(e), so as to allow the dicing tape 2 to come into contact with the exposed surface of the interposition layer 1, the laminate 64 in which the base material 4a is peeled away and the outside parts of the effective region are removed to be in a ring shape and the laminate 63 are laminated. Thereafter, the base material 4b is peeled away, and thus the dicing-tape-integrated adhesive sheet 10 illustrated in FIG. 1(f) is obtained.

While the embodiment of the method of forming the dicing tape 2 directly to the support film is described above, the dicing-tape-integrated adhesive sheet may also be manufactured by forming the adhesive layer of the dicing tape 2, the interposition layer 1, and the adhesive film 3 on the support film in a desirable order.

In addition, the dicing-tape-integrated adhesive sheet may also be manufactured by applying the base material 4b of the adhesive film 3 as the interposition layer as it is and forming the adhesive layer of the dicing tape 2, the interposition layer 1 (the base material 4b), and the adhesive film 3 on the support film in a desirable order.

In addition, the interposition layer 1, the adhesive layer of the dicing tape 2, and the adhesive film 3 have different adhesions, and preferably have the following properties.

First, the adhesion of the interposition layer 1 to the adhesive film 3 is preferably smaller than the adhesion of the interposition layer 1 to the adhesive layer of the dicing tape 2 and the adhesion of the adhesive layer of the dicing tape 2 to the support film 4. Accordingly, in a third process, which will be described later, when an individual piece 83 is picked up, without separation between the adhesive layer of the dicing tape 2 and the support film 4, the adhesive film 3 and the interposition layer 1 are selectively peeled away from each other. In addition, during dicing, a laminate 8 can be continuously, reliably supported by the wafer ring 9.

### (Semiconductor Device, Multilayered Circuit Board, and Electronic Component)

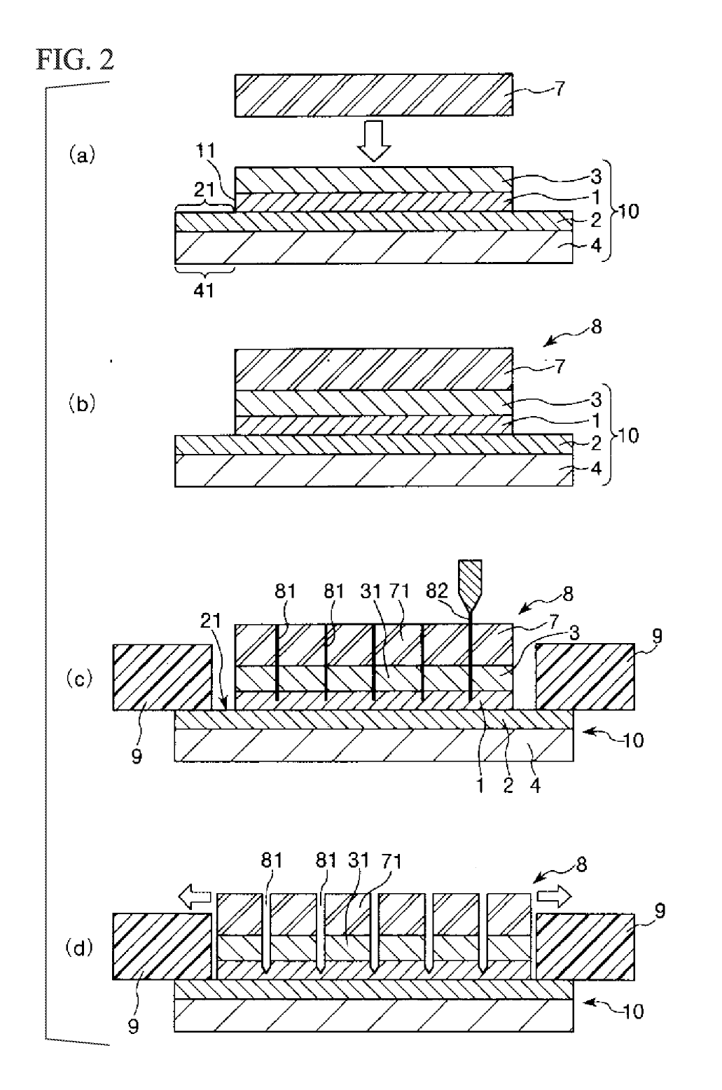

Next, a semiconductor device, a multilayered circuit board, and an electronic component which are manufactured by using the above-described dicing-tape-integrated adhesive sheet will be described.

[1] As illustrated in FIG. 2(a), while the adhesive film 3 of the dicing-tape-integrated adhesive sheet 10 as described above and the semiconductor wafer 7 are allowed to come into close contact with each other, the dicing-tape-integrated adhesive sheet 10 and the semiconductor wafer (support body) 7 are laminated (first process). Here, in the semiconductor wafer (support body) 7, a surface which is adhered to the adhesive film 3 has a first terminal (not illustrated). In addition, in the dicing-tape-integrated adhesive sheet 10 illustrated in FIG. 2, the size and the shape of the adhesive film 3 in a plan view are set in advance to be much smaller than the outside diameter of the semiconductor wafer 7 or larger than the outside diameter thereof and to be smaller than the inside diameter of the wafer ring 9. Therefore, the entire lower surface of the semiconductor wafer 7 comes into close contact with the entire upper surface of the adhesive film 3, and thus the semiconductor wafer 7 is supported by the dicing-tape-integrated adhesive sheet 10. The dicing-tape-integrated adhesive sheet 10 is laminated so that the first terminal of the semiconductor wafer 7 is covered with the adhesive film 3 (FIG. 2(b)).

Examples of a method of laminating the dicing-tape-integrated adhesive sheet 10 on the semiconductor wafer 7 include a roll laminator, a flat-plate press, and a wafer laminator.

Among these, a method of performing lamination under vacuum (vacuum laminator) is preferable so that air is not incorporated during lamination.

In addition, lamination conditions are not particularly limited, and lamination may be performed with no voids. Specifically, a condition of heating at 60 to 150° C. for 1 to 120 seconds is preferable, and a condition of heating at 80 to 120° C. for 5 to 60 seconds is particularly preferable. When the lamination conditions are in the above range, the balance between tackiness, an effect of suppressing projections of a resin, and a curing degree of a resin is excellent.

In addition, although pressurization conditions are not particularly limited, a pressure of 0.2 to 2.0 MPa is preferable, and a pressure of 0.5 to 1.5 MPa is particularly preferable.

From the lamination results, as illustrated in FIG. 2(b), the laminate 8 in which the dicing-tape-integrated adhesive sheet 10 and the semiconductor wafer 7 are laminated is obtained.

[2-1] Next, the wafer ring 9 is prepared. Subsequently, the laminate 8 and the wafer ring 9 are laminated so that the upper surface of an outer peripheral portion 21 of the adhesive layer of the dicing tape 2 and the lower surface of the wafer ring 9 come into close contact with each other. Accordingly, the outer peripheral portion of the laminate 8 is supported by the wafer ring 9.

The wafer ring 9 is generally made of various metallic materials such as stainless steel or aluminum, and thus has high rigidity and can reliably prevent deformation of the laminate 8.

[2-2] Next, a dicer table (not illustrated) is prepared, and the laminate 8 is placed on the dicer table so that the dicer table and the support film 4 come into contact with each other.

Subsequently, as illustrated in FIG. 2(c), a plurality of cuts 81 are formed in the laminate 8 by using a dicing blade 82 (dicing). The dicing blade 82 is configured as a disk-like diamond blade or the like and is pressed against the surface of the laminate 8 on the semiconductor wafer 7 side while being rotated such that the cuts 81 are formed. In addition, by relatively moving the dicing blade 82 along a gap between circuit patterns formed in the semiconductor wafer 7, the semiconductor wafer 7 is divided into a plurality of semiconductor chips 71 (second process). In addition, the adhesive film 3 is also divided into a plurality of adhesive films 31. During the dicing as such, vibrations or impacts are applied to the semiconductor wafer 7. However, since the lower surface of the semiconductor wafer 7 is supported by the dicing-tape-integrated adhesive sheet 10, vibrations or impacts mentioned above can be reduced. As a result, the occurrence of defects such as breakage or cracking in the semiconductor wafer 7 can be reliably prevented.

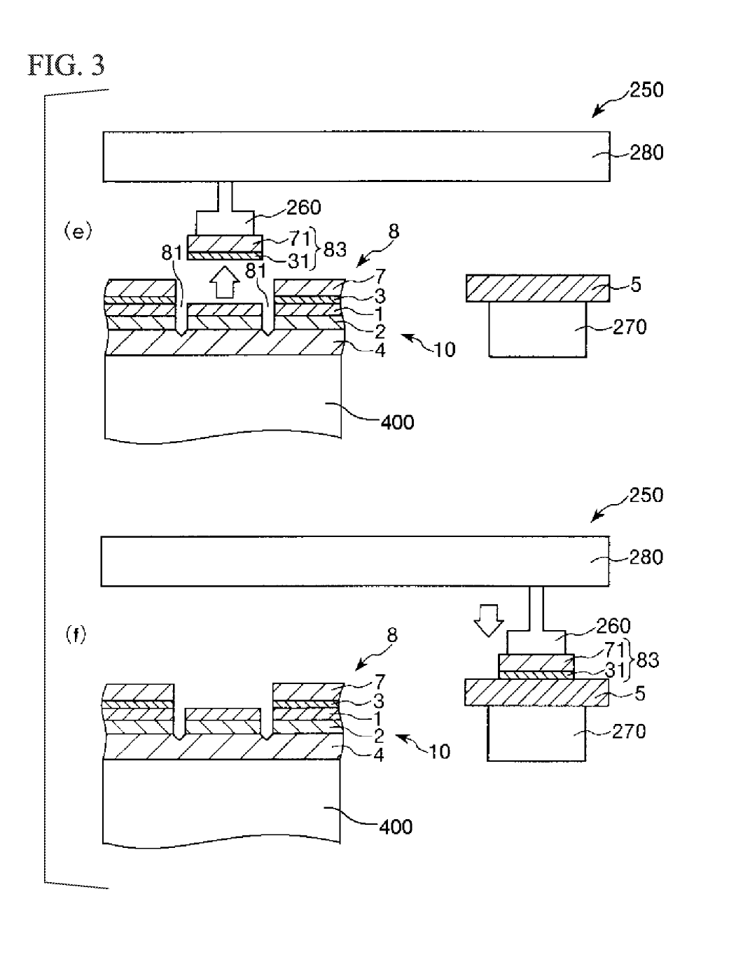

In the second process, the cut depth may be set so that the tip end of the dicing blade 82 stays in the interposition layer 1. In other words, the dicing is performed so that the tip end of the cut 81 does not reach the support film 4 but stays in the interposition layer 1 or the adhesive layer of the dicing tape 2. Accordingly, shavings of the support film 4 are not generated, and thus a problem accompanied by the generation of the shavings can be reliably solved. That is, an occurrence of a hitch or the like is prevented when the semiconductor chip 71 is picked up, and thus infiltration of foreign matter and poor soldering can be prevented when the picked-up semiconductor chip 71 is mounted on an adherend 5. As a result, the manufacturing yield of a semiconductor device 100 is increased, and the semiconductor device 100 having high reliability can be obtained.

[3-1] Next, the laminate 8 in which the plurality of cuts 81 are formed is allowed to radially extend by an expanding device (not illustrated) (expansion). Accordingly, as illustrated in FIG. 2(d), the width of the cut 81 formed in the laminate 8 widens, and thus the gaps between the divided semiconductor chips 71 also expand. As a result, there is no concern that the semi conductor chips 71 interfere with each other, and thus the individual semiconductor chips 71 can be easily picked up. In addition, the expanding device is configured to allow the expansion state to be maintained in the process described later.

[3-2] Next, by a die bonder 250, one of the divided semiconductor chips 71 is sucked by a collet (chip suction portion) 260 of the die bonder and is pulled up. As a result, as illustrated in FIG. 3(e), the interface between the adhesive film 31 and the interposition layer 1 is selectively peeled, and an individual piece 83 in which the semiconductor chip 71 and the adhesive film 31 are laminated is picked up (third process).

In addition, the reason that the interface between the adhesive film 31 and the interposition layer 1 is selectively peeled is because, as described above, the tackiness of the adhesive layer of the dicing tape 2 is higher than the tackiness of the interposition layer 1 and the adhesion of the interface between the support film 4 and the adhesive layer of the dicing tape 2 and the adhesion of the interface between the adhesive layer of the dicing tape 2 and the interposition layer 1 are greater than the adhesion between the interposition layer 1 and the adhesive film 3. That is, in a case where the semiconductor chip 71 is picked upward, among these three interfaces, the interface of the interposition layer 1 and the adhesive film 3 which has the smallest adhesion is selectively peeled.

In addition, when the individual piece 83 is picked up, the individual piece 83 which is to be picked up may be selectively pushed up by a push-up unit 400 from below the dicing-tape-integrated adhesive sheet 10. Accordingly, the individual piece 83 is pushed up from the laminate 8, and thus the picking-up of the individual piece 83 can be easily performed. In addition, for the pushing-up of the individual piece 83, a needle-like body (needle) which pushes up the dicing-tape-integrated adhesive sheet 10 from below, or the like is used (not illustrated).

In addition, in a case where the laminate 8 does not contain the interposition layer 1 and the adhesive layer 2 contains the photo-curable component, after the second process and before the third process, the dicing-tape-integrated adhesive sheet 10 is irradiated with ultraviolet light, an electron beam or the like from below so that the photo-curable component contained in the adhesive layer 2 is subjected to a photo-curing reaction to reduce the tackiness. In this manner, the adhesion between the adhesive layer 2 and the adhesive film 3 is reduced, and thus the interface between the adhesive layer 2 and the adhesive film 3 is selectively peeled in the case where the semiconductor chip 71 is picked upward.

[4-1] Next, the adherend 5 for mounting the semiconductor chip 71 is prepared.

A surface of the adherend 5, which is adhered to the adhesive film 3, includes a second terminal (not illustrated). As the adherend 5, a substrate, a semiconductor chip, or the like which has the semiconductor chip 71 mounted thereon and includes wiring for electrical connection of the semiconductor chip 71 to the outside may be employed.

In addition, examples of the first terminal and the second terminal include an electrode pad and a solder bump. In addition, it is preferable that solder be present in at least one of the first terminal and the second terminal.

Subsequently, as illustrated in FIG. 3(f), the picked-up individual piece 83 is placed on the adherend 5. At this time, the first terminal of the semiconductor chip 71 and the second terminal of the adherend 5 are temporarily pressed against each other with the adhesive film 3 interposed therebetween while being aligned with each other.

[4-2] Next, the adherend 5 and the semiconductor chip 71 are soldered together (fourth process).

Soldering conditions depend on the type of the solder used. For example, in a case of Sn—Ag, it is preferable that soldering be performed by heating at 220 to 260° C. for 5 to 500 seconds, and heating at 230 to 240° C. for 10 to 100 seconds is particularly preferable.

It is preferable that the soldering be performed under the conditions in which the adhesive film 3 is cured after the solder is melted. That is, it is preferable that the soldering be performed under the conditions in which although the solder is melted, the curing reaction of the adhesive film 3 does not proceed too much. Accordingly, the shape of the soldered portion during the soldering can be a stable shape having excellent connection reliability.

Next, the adhesive film 3 is heated and cured (fifth process). Curing conditions are not particularly limited, but a condition of heating at 130 to 220° C. for 30 to 500 minutes is preferable, and a condition of heating at 150 to 200° C. for 60 to 180 minutes is particularly preferable.

According to the method described above, in the third process, the picking-up is performed in the state where the adhesive film 31 is adhered to the semiconductor chip 71, that is, the state of the individual piece 83. Therefore, in the fourth process, the adhesive film 31 can be directly used to be adhered to the adherend 5. Therefore, by using the dicing-tape-integrated adhesive sheet of the present invention, there is no need to prepare an additional underfill material or the like, and the manufacturing efficiency of the semiconductor device 100 in which the semiconductor chip 71 and the adherend 5 are electrically connected to each other using the solder can be further increased.

In addition, as the support body 7 and the adherend 5, for example, a chip, a board (circuit board), a wafer, and the like may be employed. In a case where a circuit board is used as each of the support body 7 and the adherend 5, a multilayered circuit board which is joined by the cured material of the adhesive film 3 can be obtained. In addition, in a case where a semiconductor chip is used as each of the support body 7 and the adherend 5, an electronic component which is joined by the cured material of the adhesive film 3 can be obtained.

Hereinafter, the present invention will be described in detail on the basis of Examples and Comparative Examples, but the present invention is not limited thereto.

### EXAMPLES

### Example 1

### Formation of Interposition Layer

100 parts by weight of a copolymer having a weight-average molecular weight of 300,000, which was obtained by copolymerizing 30 weight % of 2-ethylhexyl acrylate and 70 weight % of vinyl acetate, 45 parts by weight of a pentafunctional acrylate monomer having a molecular weight of 700, 5 parts by weight of 2,2-dimethoxy-2-phenylacetophenone, 3 parts by weight of tolylene diisocyanate (CORONATE T-100 manufactured by NIPPON POLYURETHANE INDUSTRY CO., LTD.) were applied to a polyester film having a thickness of 38 μm, which was subjected to a release treatment, to have a thickness of 10 μm, and thereafter the resultant was dried for 5 minutes at 80° C. In addition, the obtained applied film was irradiated with ultraviolet light at 500 mJ/cm², thereby forming an interposition layer on the polyester film.

### <Formation of Adhesive Layer of Dicing Tape>

100 parts by weight of a copolymer having a weight-average molecular weight of 500,000, which was obtained by copolymerizing 70 weight % of butyl acrylate and 30 weight % of 2-ethylhexyl acrylate, and 3 parts by weight of tolylene diisocyanate (CORONATE T-100 manufactured by NIPPON POLYURETHANE INDUSTRY CO., LTD.) were adjusted, thereby adjusting a varnish for an adhesive layer of a dicing tape. The varnish for the adhesive layer of the dicing tape was applied to a polyester film having a thickness of 38 μm, which was subjected to a release treatment, to have a thickness of 10 μm after drying, and thereafter the resultant was dried at 80° C. for 5 minutes. In addition, the adhesive layer of the dicing tape was formed on the polyester film. Thereafter, a polyethylene sheet having a thickness of 100 μm was laminated as a support film.

### <Preparation of Varnish for Adhesive Film>

20.4 parts by weight of a cresol novolac resin (KA-1160 manufactured by DIC Corporation), 56.8 parts by weight of a bisphenol F type epoxy resin (EXA-830LVP manufactured by DIC Corporation). 15.0 parts by weight of trimellitic acid (manufactured by Tokyo Chemical Industry Co., Ltd.) as the compound having the flux activity function, 7.2 parts by weight of a phenoxy resin (YX-6954 manufactured by Mitsubishi Chemical Corporation) as the film-forming resin, 0.1 parts by weight of 2-phenyl-4-methylimidazole (2P4MZ manufactured by Shikoku Chemicals Corporation) as the curing accelerator, and 0.5 parts by weight of β-(3,4-epoxycyclohexyl)ethyl trimethoxysilane (KBM-403 manufactured by Shin-Etsu Chemical Co., Ltd.) as the silane coupling agent were dissolved in methyl ethyl ketone, thereby preparing a resin varnish having a resin concentration of 50%.

### <Production of Adhesive Film>

The obtained varnish for an adhesive film was applied to a base polyester film (base film, trade name Lumirror, manufactured by TORAY INDUSTRIES, INC.) to have a thickness of 50 μm, and the resultant was dried at 100° C. for 5 minutes, thereby obtaining the adhesive film having a thickness of 25 μm.

### <Production of Dicing-Tape-Integrated Adhesive Sheet>

The film on which the interposition layer was formed, and the film on which the adhesive film was formed were laminated to allow the interposition layer and the adhesive film to come into contact with each other, thereby obtaining a laminate.

Next, the interposition layer and the adhesive film were punched by using a roll-shaped mold to have a diameter greater than the outside diameter of the semiconductor wafer and smaller than the inside diameter of the wafer ring, and thereafter unnecessary parts thereof on the outside were removed, thereby obtaining a second laminate.

Further, the polyester film on the one surface of the adhesive layer of the dicing tape was peeled. In addition, the laminates were laminated to allow the interposition layer of the second laminate and the adhesive layer of the dicing tape to come into contact with each other. Accordingly, a dicing-tape-integrated adhesive sheet in which five layers including the laminate (the dicing tape) of the polyethylene sheet (the support film) and the adhesive layer of the dicing tape, the interposition layer, the adhesive film, and the polyester film (outer layer) were laminated in this order was obtained.

### <Production of Semiconductor Device>

A silicon wafer (having a diameter of 8 inches and a thickness of 100 jam) having a solder bump was prepared. The polyester film was peeled away from the dicing-tape-integrated adhesive sheet, and the dicing-tape-integrated adhesive sheet and the silicon wafer were laminated to allow the peeled surface and a surface of the silicon wafer having the solder bump to come into contact with each other. The resultant was laminated by a laminator at an adhesion temperature T of 80° C. and a pressure P applied to the adhesive film (the dicing-tape-integrated adhesive sheet) of 0.8 MPa for 30 seconds, thereby obtaining a silicon wafer having the dicing-tape-integrated adhesive sheet.

In addition, under the same condition except that the adhesion temperature T was changed to 150° C. and the pressure applied to the adhesive film (the dicing-tape-integrated adhesive sheet) was changed to 0.3 MPa, a semiconductor device was produced.

Next, the silicon wafer having the dicing-tape-integrated adhesive sheet was diced (cut) from the silicon wafer side by using a dicing saw (DFD6360 manufactured by DISCO Corporation) under the following condition. Accordingly, the silicon wafer was divided, thereby obtaining semiconductor chips having the following dicing sizes.

### <Dicing Condition>

Dicing Sizes: 10 mm×10 mm size

Dicing Speed: 50 mm/sec

Spindle rotations: 40,000 rpm

Dicing maximum depth: 0.130 mm (cut depth from the surface of the silicon wafer)

Thickness of dicing blade: 15 μm

Transverse cross-sectional area of cut depth: 7.5×10⁵ mm² (the cross-sectional area of a part on the tip end side from the interface between the adhesive film and the interposition layer)

In addition, the depth of the tip end of the cut formed by dicing had reached the inside of the interposition layer.

Next, one of the semiconductor chips was pushed up by a needle from the support film side (rear surface) of the dicing-tape-integrated adhesive sheet, and the semiconductor chip was pulled up while the surface of the pushed semiconductor chip was adsorbed by a collet of a die bonder. Accordingly, the semiconductor chip having the adhesive film was picked up.

Next, while alignment was performed to allow a pad of a circuit board having the pad to contact on the solder bump, the semiconductor chip on the circuit board was heated at 235° C. for 5 seconds to melt the solder bump, thereby performing soldering.

In addition, the resultant was heated under the atmosphere having a fluid pressure (air pressure) of 0.8 MPa at 180° C. for 60 minutes to cure the adhesive film, thereby obtaining a semiconductor device in which the semiconductor chip and the circuit board were adhered by the cured material of the adhesive film.

### Example 2

A dicing-tape-integrated adhesive sheet and a semiconductor device were produced in the same manner as in Example 1 except that a varnish for an adhesive film was produced as follows.

### <Preparation of Varnish for Adhesive Film>

The varnish for the adhesive film was prepared in the same manner as in Example 1 except that 20.4 parts by weight of the cresol novolac resin (KA-1160 manufactured by DIC Corporation) was changed to 15.0 parts by weight thereof, 56.8 parts by weight of the bisphenol F type epoxy resin (EXA-830LVP manufactured by DIC Corporation) was changed to 45.0 parts by weight of a bisphenol A type epoxy resin (EPICLON-840S manufactured by DIC Corporation), 15.0 parts by weight of the trimellitic acid (manufactured by Tokyo Chemical Industry Co., Ltd.) was changed to 15.0 parts by weight of 2,3-naphthalenedicarboxylic acid (manufactured by Tokyo Chemical Industry Co., Ltd.), 7.2 parts by weight of the phenoxy resin (YX-6954 manufactured by Mitsubishi Chemical Corporation) was changed to 24.4 parts by weight of a urethane acrylate polymer (UN-9200A manufactured by Negami Chemical Industrial Co., Ltd.), 0.1 parts by weight of 2-phenyl-4-methylimidazole (2P4MZ manufactured by Shikoku Chemicals Corporation) was changed to 0.1 parts by weight of 2-phenyl-4,5-dihydroxymethyl imidazole (2PHZ-PW manufactured by Shikoku Chemicals Corporation), and 0.5 parts by weight of β-(3,4-epoxycyclohexyl)ethyl trimethoxysilane (KBM-403 manufactured by Shin-Etsu Chemical Co., Ltd.) was changed to 0.5 parts by weight of 3-aminopropyltriethoxysilane (KBE-903 manufactured by Shin-Etsu Chemical Co., Ltd.).

### Example 3

A dicing-tape-integrated adhesive sheet and a semiconductor device were produced in the same manner as in Example 1 except that a varnish for an adhesive film was produced as follows.

### <Preparation of Varnish for Adhesive Film>

The varnish for the adhesive film was prepared in the same manner as in Example 1 except that 20.4 parts by weight of the cresol novolac resin (KA-1160 manufactured by DIC Corporation) was changed to 10.1 parts by weight of a biphenylaralkyl type phenol (MEH-785111 manufactured by Meiwa Plastic Industries, Ltd.), 56.8 parts by weight of the bisphenol F type epoxy resin (EXA-830LVP manufactured by DIC Corporation) was changed to 31.0 parts by weight thereof, 15.0 parts by weight of the trimellitic acid (manufactured by Tokyo Chemical Industry Co., Ltd.) was changed to 11.2 parts by weight of phenolphthalein (manufactured by Tokyo Chemical Industry Co., Ltd.), 7.2 parts by weight of the phenoxy resin (YX-6954 manufactured by Mitsubishi Chemical Corporation) was changed to 14.5 parts by weight of a methacrylic acid ester-based polymer (M-4003 manufactured by Negami Chemical Industrial Co., Ltd.) and 7.3 parts by weight of a urethane acrylate polymer (UN-9200A manufactured by Negami Chemical Industrial Co., Ltd.), 0.1 parts by weight of 2-phenyl-4-methylimidazole (2P4MZ manufactured by Shikoku Chemicals Corporation) was changed to 0.2 parts by weight thereof, 0.5 parts by weight of β-(3,4-epoxycyclohexyl)ethyl trimethoxysilane (KBM-403 manufactured by Shin-Etsu Chemical Co., Ltd.) was changed to 0.7 parts by weight thereof, and 25.0 parts by weight of a silica filler (SC1050 manufactured by Admatechs Company Limited) was added.

### Example 4

A dicing-tape-integrated adhesive sheet and a semiconductor device were produced in the same manner as in Example 1 except that a varnish for an adhesive film was produced as follows.

### <Preparation of Varnish for Adhesive Film>

The varnish for the adhesive film was prepared in the same manner as in Example 1 except that 20.4 parts by weight of the cresol novolac resin (KA-1160 manufactured by DIC Corporation) was changed to 4.4 parts by weight of a phenol novolac resin (PR-55617 manufactured by Sumitomo Bakelite Co., Ltd.), 56.8 parts by weight of the bisphenol F type epoxy resin (EXA-830LVP manufactured by DIC Corporation) was changed to 14.0 parts by weight of a cresol novolac type epoxy resin (YDCN-700-5 manufactured by NIPPON STEEL CHEMICAL CO., LTD.), 15.0 parts by weight of the trimellitic acid (manufactured by Tokyo Chemical Industry Co., Ltd.) was changed to 6.8 parts by weight of 2,3-naphthalenedicarboxylic acid (manufactured by Tokyo Chemical Industry Co., Ltd.), 7.2 parts by weight of the phenoxy resin (YX-6954 manufactured by Mitsubishi Chemical Corporation) was changed to 18.4 parts by weight of a methacrylic acid ester-based polymer (M-4003 manufactured by Negami Chemical Industrial Co., Ltd.), 0.1 parts by weight of 2-phenyl-4-methylimidazole (2P4MZ manufactured by Shikoku Chemicals Corporation) was changed to 0.3 parts by weight thereof, 0.5 parts by weight of β-(3,4-epoxycyclohexyl)ethyl trimethoxysilane (KBM-403 manufactured by Shin-Etsu Chemical Co., Ltd.) was changed to 1.1 parts by weight thereof, and 55.0 parts by weight of a silica filler (SC1050 manufactured by Admatechs Company Limited) was added.

### Example 5

A dicing-tape-integrated adhesive sheet and a semiconductor device were produced in the same manner as in Example 1 except that a varnish for an adhesive film was produced as follows,

### <Preparation of Varnish for Adhesive Film>

The varnish for the adhesive film was prepared in the same manner as in Example 1 except that 20.4 parts by weight of the cresol novolac resin (KA-1160 manufactured by DIC Corporation) was changed to 3.0 parts by weight of a phenol novolac resin (PR-55617 manufactured by Sumitomo Bakelite Co., Ltd.), 56.8 parts by weight of the bisphenol F type epoxy resin (EXA-830LVP manufactured by DIC Corporation) was changed to 8.3 parts by weight thereof, 15.0 parts by weight of the trimellitic acid (manufactured by Tokyo Chemical Industry Co., Ltd.) was changed to 4.5 parts by weight thereof, 7.2 parts by weight of the phenoxy resin (YX-6954 manufactured by Mitsubishi Chemical Corporation) was changed to 12.6 parts by weight of a methacrylic acid ester-based polymer (M-4003 manufactured by Negami Chemical Industrial Co., Ltd.), 0.1 parts by weight of 2-phenyl-4-methylimidazole (2P4MZ manufactured by Shikoku Chemicals Corporation) was changed to 0.3 parts by weight 2-phenyl-4,5-dihydroxymethyl imidazole (2PHZ-PW manufactured by Shikoku Chemicals Corporation), 0.5 parts by weight of β-(3,4-epoxycyclohexyl)ethyl trimethoxysilane (KBM-403 manufactured by Shin-Etsu Chemical Co., Ltd.) was changed to 1.3 parts by weight of 3-aminopropyltriethoxysilane (KBE-903 manufactured by Shin-Etsu Chemical Co., Ltd.), and 70.0 parts by weight of a silica filler (SC1050 manufactured by Admatechs Company Limited) was added.

### Example 6

### Production of Support Film

As material resins included in the support film, 60 parts by weight of polypropylene and 40 parts by weight of a block copolymer made of a polystyrene segment expressed by General Formula (1) and a vinyl polyisoprene segment expressed by General Formula (2) were prepared.

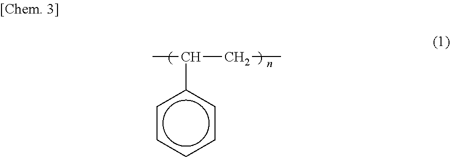

(In Formula (1), n is an integer of 2 or greater)

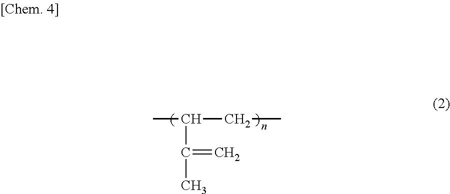

(In Formula (2), n is an integer of 2 or greater)

After kneading the materials included in the support film using a biaxial kneader, the kneaded materials were extruded by an extruder, thereby producing the support film having a thickness of 100 ram.

### <Formation of Dicing Tape>

As an acrylic adhesive, a resin (hereinafter, referred to as “base resin A”) made of 10 parts by weight of a first copolymer and 90 parts by weight of a second copolymer was prepared. As the first copolymer, a copolymer having a weight-average molecular weight of 500,000, which was obtained by copolymerizing 70 parts by weight of butyl acrylate, 25 parts by weight of 2-ethylhexyl acrylate, and 5 parts by weight of vinyl acetate was used. As the second copolymer, a copolymer having a weight-average molecular weight of 300,000, which was obtained by copolymerizing 50 parts by weight of 2-ethylhexyl acrylate, 10 parts by weight of butyl acrylate, 37 parts by weight of vinyl acetate, and 3 parts by weight of 2-hydroxyethyl methacrylate was used.

As a photo-curable component, 140 parts by weight of urethane acrylate of a pentakaidecafunctional oligomer (product number: Miramer SC2152 manufactured by Miwon Specialty Chemical Co., Ltd.) with respect to 100 parts by weight of the acrylic adhesive was prepared. As a crosslinking agent, 5 parts by weight of polyisocyanate (product number: CORONATE L, manufactured by NIPPON POLYURETHANE INDUSTRY CO., LTD.) with respect to 100 parts by weight of the acrylic adhesive was prepared. As a photoinitiator, 3 parts by weight of benzyl dimethyl ketal (product number: Irgacure 651, manufactured by Chiba Specialty Chemicals Co., Ltd.) with respect to 100 parts by weight of the acrylic adhesive was prepared.

A resin solution of a first resin composition in which the acrylic adhesive, the photo-curable component, the crosslinking agent, and the photoinitiator were blended was produced. The resin solution was applied to a polyester film having a thickness of 38 μm, which was subjected to a release treatment, to have a thickness of 10 μm, and thereafter the resultant was dried for 5 minutes at 80° C. In addition, an adhesive layer of a dicing tape was formed on the polyester film. Thereafter, the support film was laminated.

### <Production of Adhesive Film>

20.4 parts by weight of a cresol novolac resin (KA-1160 manufactured by DIC Corporation), 56.8 parts by weight of a bisphenol F type epoxy resin (EXA-830LVP manufactured by DIC Corporation), 15.0 parts by weight of trimellitic acid (manufactured by Tokyo Chemical Industry Co., Ltd.) as the compound having the flux activity function, 7.2 parts by weight of a phenoxy resin (YX-6954 manufactured by Mitsubishi Chemical Corporation) as the film-forming resin, 0.1 parts by weight of 2-phenyl-4-methylimidazole (2P4MZ manufactured by Shikoku Chemicals Corporation) as the curing accelerator, and 0.5 parts by weight of fl-(3,4-epoxycyclohexyl)ethyl trimethoxysilane (KBM-403 manufactured by Shin-Etsu Chemical Co., Ltd.) as the silane coupling agent were dissolved in methyl ethyl ketone, thereby preparing a resin varnish having a resin concentration of 50%.

### <Production of Adhesive Film>

The obtained varnish for an adhesive film was applied to a base polyester film (base film, trade name Lumirror, manufactured by TORAY INDUSTRIES, INC.) to have a thickness of 50 μm, and the resultant was dried at 100° C. for 5 minutes, thereby obtaining the adhesive film having a thickness of 25 μm.

### <Production of Dicing-Tape-Integrated Adhesive Sheet>

The film on which the adhesive film was formed was punched to have a diameter greater than the outside diameter of a semiconductor wafer and smaller than the inside diameter of a wafer ring, and thereafter unnecessary parts thereof on the outside were removed.

Further, the polyester film on the one surface of the adhesive layer of the dicing tape, which was subjected to a release treatment, was peeled. In addition, the punched adhesive film and the adhesive layer of the dicing tape were laminated to come into contact with each other. Accordingly, a dicing-tape-integrated adhesive sheet in which four layers including the laminate (the dicing tape) of the support film and the adhesive layer of the dicing tape, the adhesive film, and the polyester film (outer layer) were laminated in this order was obtained.

### <Production of Semiconductor Device>

A silicon wafer (having a diameter of 8 inches and a thickness of 100 μm) having a solder bump was prepared. The polyester film was peeled away from the dicing-tape-integrated adhesive sheet, and the dicing-tape-integrated adhesive sheet and the silicon wafer were laminated to allow the peeled surface and a surface of the silicon wafer having the solder bump to come into contact with each other. The resultant was laminated by a laminator at an adhesion temperature T of 80° C. and a pressure P applied to the adhesive film (the dicing-tape-integrated adhesive sheet) of 0.8 MPa for 30 seconds, thereby obtaining a silicon wafer having the dicing-tape-integrated adhesive sheet.

In addition, under the same condition except that the adhesion temperature T was changed to 150° C. and the pressure applied to the adhesive film (the dicing-tape-integrated adhesive sheet) was changed to 0.3 MPa, a semiconductor device was produced.

Next, the silicon wafer having the dicing-tape-integrated adhesive sheet was diced (cut) from the silicon wafer side by using a dicing saw (DFD6360 manufactured by DISCO Corporation) under the following condition. Accordingly, the silicon wafer was divided, thereby obtaining semiconductor chips having the following dicing sizes.

### <Dicing Condition>

Dicing Sizes: 10 mm×10 mm size

Dicing Speed: 50 mm/sec

Spindle rotations: 40,000 rpm

Dicing maximum depth: 0.080 mm (height from the surface of a dicing table)

Thickness of dicing blade: 15 μm

Next, ultraviolet light was irradiated from the support film side (rear surface) of the dicing-tape-integrated adhesive sheet.

Thereafter, one of the semiconductor chips was pushed up by a needle from the rear surface of the dicing-tape-integrated adhesive sheet, and the semiconductor chip was pulled up while the surface of the pushed semiconductor chip was adsorbed by a collet of a die bonder. Accordingly, the semiconductor chip having the adhesive film was picked up.

Next, while alignment was performed to allow a, pad of a circuit board having the pad to contact on the solder bump, the semiconductor chip on the circuit board was heated at 235° C. for 5 seconds to melt the solder bump, thereby performing soldering.

In addition, the resultant was heated under the atmosphere having a fluid pressure (air pressure) of 0.8 MPa at 180° C. for 60 minutes to cure the adhesive film, thereby obtaining a semiconductor device in which the semiconductor chip and the circuit board were adhered by the cured material of the adhesive film.

### Example 7

A dicing-tape-integrated adhesive sheet and a semiconductor device were produced in the same manner as in Example 6 except that a varnish for an adhesive film was produced as follows.

### <Preparation of Varnish for Adhesive Film>

The varnish for the adhesive film was prepared in the same manner as in Example 6 except that 20.4 parts by weight of the cresol novolac resin (KA-1160 manufactured by DIC Corporation) was changed to 15.0 parts thereof, 56.8 parts by weight of the bisphenol F type epoxy resin (EXA-830LVP manufactured by DIC Corporation) was changed to 45.0 parts by weight of a bisphenol A type epoxy resin (EPICLON-840S manufactured by DIC Corporation), 15.0 parts by weight of the trimellitic acid (manufactured by Tokyo Chemical Industry Co., Ltd.) was changed to 15.0 parts by weight 2,3-naphthalenedicarboxylic acid (manufactured by Tokyo Chemical Industry Co., Ltd.), 7.2 parts by weight of the phenoxy resin (YX-6954 manufactured by Mitsubishi Chemical Corporation) was changed to 24.4 parts by weight of a urethane acrylate polymer (UIN-9200A manufactured by Negami Chemical Industrial Co., Ltd.), 0.1 parts by weight of 2-phenyl-4-methylimidazole (2P4MZ manufactured by Shikoku Chemicals Corporation) was changed to 0.1 parts by weight of 2-phenyl-4,5-dihydroxymethyl imidazole (2PHZ-PW manufactured by Shikoku Chemicals Corporation), and 0.5 parts by weight of β-(3,4-epoxycyclohexyl)ethyl trimethoxysilane (KBM-403 manufactured by Shin-Etsu Chemical Co., Ltd.) was changed to 0.5 parts by weight of 3-aminopropyltriethoxysilane (KBE-903 manufactured by Shin-Etsu Chemical Co., Ltd.).

### Example 8

A dicing-tape-integrated adhesive sheet and a semiconductor device were produced in the same manner as in Example 6 except that a varnish for an adhesive film was produced as follows.

### <Preparation of Varnish for Adhesive Film>

The varnish for the adhesive film was prepared in the same manner as in Example 6 except that 20.4 parts by weight of the cresol novolac resin (KA-1160 manufactured by DIC Corporation) was changed to 10.1 parts by weight of a biphenylaralkyl type phenol (MEH-7851H manufactured by Meiwa Plastic Industries, Ltd.), 56.8 parts by weight of the bisphenol F type epoxy resin (EXA-830LVP manufactured by DIC Corporation) was changed to 31.0 parts by weight thereof, 15.0 parts by weight of the trimellitic acid (manufactured by Tokyo Chemical Industry Co., Ltd.) was changed to 11.2 parts by weight of phenolphthalein (manufactured by Tokyo Chemical Industry Co., Ltd.), 7.2 parts by weight of the phenoxy resin (YX-6954 manufactured by Mitsubishi Chemical Corporation) was changed to 14.5 parts by weight of a methacrylic acid ester-based polymer (M-4003 manufactured by Negami Chemical Industrial Co., Ltd.) and 7.3 parts by weight of a urethane acrylate polymer (UN-9200A manufactured by Negami Chemical Industrial Co., Ltd.), 0.1 parts by weight of 2-phenyl-4-methylimidazole (2P4MZ manufactured by Shikoku Chemicals Corporation) was changed to 0.2 parts by weight thereof, 0.5 parts by weight of β-(3,4-epoxycyclohexyl)ethyl trimethoxysilane (KBM-403 manufactured by Shin-Etsu Chemical Co., Ltd.) was changed to 0.7 parts by weight thereof, and 25.0 parts by weight of a silica filler (SC1050 manufactured by Admatechs Company Limited) was added.

### Example 9

A dicing-tape-integrated adhesive sheet and a semiconductor device were produced in the same manner as in Example 6 except that a varnish for an adhesive film was produced as follows.

### <Preparation of Varnish for Adhesive Film>

The varnish for the adhesive film was prepared in the same manner as in Example 6 except that 20.4 parts by weight of the cresol novolac resin (KA-1160 manufactured by DIC Corporation) was changed to 4.4 parts by weight of a phenol novolac resin (PR-55617 manufactured by Sumitomo Bakelite Co., Ltd.), 56.8 parts by weight of the bisphenol F type epoxy resin (EXA-830LVP manufactured by DIC Corporation) was changed to 14.0 parts by weight of a cresol novolac type epoxy resin (YDCN-700-5 manufactured by NIPPON STEEL CHEMICAL CO., LTD.), 15.0 parts by weight of the trimellitic acid (manufactured by Tokyo Chemical Industry Co., Ltd.) was changed to 6.8 parts by weight of 2,3-naphthalenedicarboxylic acid (manufactured by Tokyo Chemical Industry Co., Ltd.), 7.2 parts by weight of the phenoxy resin (YX-6954 manufactured by Mitsubishi Chemical Corporation) was changed to 18.4 parts by weight of a methacrylic acid ester-based polymer (M-4003 manufactured by Negami Chemical Industrial Co., Ltd.), 0.1 parts by weight of 2-phenyl-4-methylimidazole (2P4MZ manufactured by Shikoku Chemicals Corporation) was changed to 0.3 parts by weight thereof, 0.5 parts by weight of β-(3,4-epoxycyclohexyl)ethyl trimethoxysilane (KBM-403 manufactured by Shin-Etsu Chemical Co., Ltd.) was changed to 1.1 parts by weight thereof, and 55.0 parts by weight of a silica filler (SC1050 manufactured by Admatechs Company Limited) was added.

### Example 10

A dicing-tape-integrated adhesive sheet and a semiconductor device were produced in the same manner as in Example 6 except that a varnish for an adhesive film was produced as follows.

### <Preparation of Varnish for Adhesive Film>

The varnish for the adhesive film was prepared in the same manner as in Example 6 except that 20.4 parts by weight of the cresol novolac resin (KA-1160 manufactured by DIC Corporation) was changed to 3.0 parts by weight of a phenol novolac resin (PR-55617 manufactured by Sumitomo Bakelite Co., Ltd.), 56.8 parts by weight of the bisphenol F type epoxy resin (EXA-830LVP manufactured by DIC Corporation) was changed to 8.3 parts by weight thereof, 15.0 parts by weight of the trimellitic acid (manufactured by Tokyo Chemical Industry Co., Ltd.) was changed to 4.5 parts by weight thereof 7.2 parts by weight of the phenoxy resin (YX-6954 manufactured by Mitsubishi Chemical Corporation) was changed to 12.6 parts by weight of a methacrylic acid ester-based polymer (M-4003 manufactured by Negami Chemical Industrial Co., Ltd.), 0.1 parts by weight of 2-phenyl-4-methylimidazole (2P4MZ manufactured by Shikoku Chemicals Corporation) was changed to 0.3 parts by weight 2-phenyl-4,5-dihydroxymethyl imidazole (2PHZ-PW manufactured by Shikoku Chemicals Corporation), 0.5 parts by weight of β-(3,4-epoxycyclohexyl)ethyl trimethoxysilane (KBM-403 manufactured by Shin-Etsu Chemical Co., Ltd.) was changed to 1.3 parts by weight of 3-aminopropyltriethoxysilane (KBE-903 manufactured by Shin-Etsu Chemical Co., Ltd.), and 70.0 parts by weight of a silica filler (SC1050 manufactured by Admatechs Company Limited) was added.

### Comparative Example 1

A dicing-tape-integrated adhesive sheet and a semiconductor device were produced in the same manner as in Example 1 except that a varnish for an adhesive film was produced as follows.

### <Preparation of Varnish for Adhesive Film>

The varnish for the adhesive film was prepared in the same manner as in Example 1 except that 20.4 parts by weight of the cresol novolac resin (KA-1160 manufactured by DIC Corporation) was changed to 22.4 parts by weight of a biphenylaralkyl type phenol (MEH-7851H manufactured by Meiwa Plastic Industries, Ltd.), 56.8 parts by weight of the bisphenol F type epoxy resin (EXA-830LVP manufactured by DIC Corporation) was changed to 60.8 parts by weight thereof; 7.2 parts by weight of the phenoxy resin (YX-6954 manufactured by Mitsubishi Chemical Corporation) was changed to 1.2 parts by weight thereof, 0.5 parts by weight of β-(3,4-epoxycyclohexyl)ethyl trimethoxysilane (KBM-403 manufactured by Shin-Etsu Chemical Co., Ltd.) was changed to 0.5 parts by weight of 3-aminopropyltriethoxysilane (KBE-903 manufactured by Shin-Etsu Chemical Co., Ltd.).

### Comparative Example 2

A dicing-tape-integrated adhesive sheet and a semiconductor device were produced in the same manner as in Example 1 except that a varnish for an adhesive film was produced as follows.

### <Preparation of Varnish for Adhesive Film>

The varnish for the adhesive film was prepared in the same manner as in Example 1 except that 20.4 parts by weight of the cresol novolac resin (KA-1160 manufactured by DIC Corporation) was changed to 1.3 parts by weight of a phenol novolac resin (PR-55617 manufactured by Sumitomo Bakelite Co., Ltd.), 56.8 parts by weight of the bisphenol F type epoxy resin (EXA-830LVP manufactured by DIC Corporation) was changed to 4.0 parts by weight thereof, 15.0 parts by weight of the trimellitic acid (manufactured by Tokyo Chemical Industry Co., Ltd.) was changed to 2.0 parts by weight thereof, 7.2 parts by weight of the phenoxy resin (YX-6954 manufactured by Mitsubishi Chemical Corporation) was changed to 5.9 parts by weight of a methacrylic acid ester-based polymer (M-4003 manufactured by Negami Chemical Industrial Co., Ltd.), 0.1 parts by weight of 2-phenyl-4-methylimidazole (2P4MZ manufactured by Shikoku Chemicals Corporation) was changed to 0.3 parts by weight 2-phenyl-4,5-dihydroxymethyl imidazole (2PHZ-PW manufactured by Shikoku Chemicals Corporation), 0.5 parts by weight of β-(3,4-epoxycyclohexyl)ethyl trimethoxysilane (KBM-403 manufactured by Shin-Etsu Chemical Co., Ltd.) was changed to 1.5 parts by weight thereof, and 85.0 parts by weight of a silica filler (SC1050 manufactured by Admatechs Company Limited) was added.

The composition of the adhesive film of each of Examples and Comparative Examples is shown in Table 1.

The melt viscosity η of the adhesive film when the adhesion temperature T was 80° C. and 150° C. is also shown in Table 1. The melt viscosity of the adhesive film was measured by the following method.

A measurement sample having a thickness of 100 μm was manufactured by laminating four adhesive films having a thickness of 25 μm obtained in each of Examples and Comparative Examples, the melt viscosity thereof was measured under the condition of a parallel plate of 20 mmφ, a gap of 0.05 mm, a frequency of 0.1 Hz, and a rate of temperature increase of 10° C./min using a viscoelasticity measuring apparatus (RheoStress RS150 manufactured by HAAKE Co. Ltd.), and the minimum melt viscosity was measured as a measurement value.

TABLE 1

| | | Example | Example | Example | Example | Example | Example | Example |
|---|---|---|---|---|---|---|---|---|
| Compound Name | | 1 | 2 | 3 | 4 | 5 | 6 | 7 |
| Compound | Phenol novolac resin PR-55617 | | | | 4.4 | 3 | | |
| (A) | (manufactured by Sumitomo Bakelite Co., | | | | | | | |
| | Ltd.) | | | | | | | |
| | Cresol novolac resin KA-1160 | 20.4 | 15 | | | | 20.4 | 15 |
| | (manufactured by DIC Corporation) | | | | | | | |
| | Biphenylaralkyl type phenol MEH-7851H | | | 10.1 | | | | |
| | (manufactured by Meiwa Plastic | | | | | | | |
| | Industries, Ltd.), | | | | | | | |
| Compound | Cresol novolac type epoxy resin | | | | 14 | | | |
| (B) | YDCN-700-5 (manufactured by NIPPON | | | | | | | |
| | STEEL CHEMICAL CO., LTD.) | | | | | | | |
| | Bisphenol F type epoxy resin | 56.8 | | 31 | | 8.3 | 56.8 | |
| | EXA-830LVP (manufactured by DIC | | | | | | | |
| | Corporation) | | | | | | | |
| | Bisphenol A type epoxy resin | | 45 | | | | | 45 |
| | EPICLON-840S (manufactured by DIC | | | | | | | |
| | Corporation) | | | | | | | |
| Compound | Trimellitic acid (manufactured by Tokyo | 15 | | | | 4.5 | 15 | |
| (C) | Chemical Industry Co., Ltd.) | | | | | | | |
| | Phenolphthalein (manufactured by Tokyo | | | 11.2 | | | | |
| | Chemical Industry Co., Ltd.) | | | | | | | |
| | 2,3-Naphthalenedicarboxylic acid | | 15 | | 6.8 | | | 15 |
| | (manufactured by Tokyo Chemical | | | | | | | |
| | Industry Co., Ltd.) | | | | | | | |
| Compound | Phenoxy resin YX-6954 (manufactured by | 7.2 | | | | | 7.2 | |
| (D) | Mitsubishi Chemical Corporation) | | | | | | | |
| | Methacrylic acid ester-based polymer | | | 14.5 | 18.4 | 12.6 | | |
| | M-4003 (manufactured by Negami | | | | | | | |
| | Chemical Industrial Co., Ltd.) | | | | | | | |
| | Urethane acrylate polymer UN-9200A | | 24.4 | 7.3 | | | | 24.4 |
| | (manufactured by Negami Chemical | | | | | | | |
| | Industrial Co., Ltd.) | | | | | | | |
| Curing | 2-Phenyl-4,5-dihydroxymethyl imidazole | | 0.1 | | | 0.3 | | 0.1 |
| Accelerator | 2PHZ-PW (manufactured by Shikoku | | | | | | | |
| | Chemicals Corporation) | | | | | | | |
| | 2-Phenyl-4-methylimidazole 2P4MZ | 0.1 | | 0.2 | 0.3 | | 0.1 | |
| | (manufactured by Shikoku Chemicals | | | | | | | |
| | Corporation) | | | | | | | |
| Silane | β-(3,4-epoxycyclohexyl)ethyl | 0.5 | | 0.7 | 1.1 | | 0.5 | |
| coupling | trimethoxysilane KBM-403 (manufactured | | | | | | | |
| agent | by Shin-Etsu Chemical Co., Ltd.) | | | | | | | |
| | 3-aminopropyltriethoxysilane KBE-903 | | 0.5 | | | 1.3 | | 0.5 |
| | (manufactured by Shin-Etsu Chemical Co., | | | | | | | |
| | Ltd.) | | | | | | | |
| Filling | Spherical silica filler SC1050 | | | 25 | 55 | 70 | | |
| material | (manufactured by Admatechs Company | | | | | | | |
| | Limited), particle diameter: 0.25 μm | | | | | | | |
| Total [parts by weight] | | 100.0 | 100.0 | 100.0 | 100.0 | 100.0 | 100.0 | 100.0 |
| (B)/(C) | | 3.8 | 3.0 | 2.8 | 2.1 | 1.8 | 3.8 | 3.0 |
| Melt | 80° C. | 40 | 3800 | 7700 | 18800 | 51000 | 40 | 3800 |
| viscosity η | 150° C. | 0.2 | 2200 | 3800 | 9800 | 33000 | 0.2 | 2200 |
| [Pa · s] | | | | | | | | |

| | | Example | Example | Example | Comparative | Comparative |
|---|---|---|---|---|---|---|
| Compound Name | | 8 | 9 | 10 | Example 1 | Example 2 |
| Compound | Phenol novolac resin PR-55617 | | 4.4 | 3 | | 1.3 |
| (A) | (manufactured by Sumitomo Bakelite Co., | | | | | |
| | Ltd.) | | | | | |
| | Cresol novolac resin KA-1160 | | | | | |
| | (manufactured by DIC Corporation) | | | | | |
| | Biphenylaralkyl type phenol MEH-7851H | 10.1 | | | 22.4 | |
| | (manufactured by Meiwa Plastic | | | | | |
| | Industries, Ltd.), | | | | | |
| Compound | Cresol novolac type epoxy resin | | 14 | | | |
| (B) | YDCN-700-5 (manufactured by NIPPON | | | | | |
| | STEEL CHEMICAL CO., LTD.) | | | | | |
| | Bisphenol F type epoxy resin | 31 | | 8.3 | 60.8 | 4 |
| | EXA-830LVP (manufactured by DIC | | | | | |
| | Corporation) | | | | | |
| | Bisphenol A type epoxy resin | | | | | |
| | EPICLON-840S (manufactured by DIC | | | | | |
| | Corporation) | | | | | |
| Compound | Trimellitic acid (manufactured by Tokyo | | | 4.5 | 15 | 2 |
| (C) | Chemical Industry Co., Ltd.) | | | | | |
| | Phenolphthalein (manufactured by Tokyo | 11.2 | | | | |
| | Chemical Industry Co., Ltd.) | | | | | |
| | 2,3-Naphthalenedicarboxylic acid | | 6.8 | | | |
| | (manufactured by Tokyo Chemical | | | | | |
| | Industry Co., Ltd.) | | | | | |
| Compound | Phenoxy resin YX-6954 (manufactured by | | | | 1.2 | |
| (D) | Mitsubishi Chemical Corporation) | | | | | |
| | Methacrylic acid ester-based polymer | 14.5 | 18.4 | 12.6 | | 5.9 |
| | M-4003 (manufactured by Negami | | | | | |
| | Chemical Industrial Co., Ltd.) | | | | | |
| | Urethane acrylate polymer UN-9200A | 7.3 | | | | |
| | (manufactured by Negami Chemical | | | | | |
| | Industrial Co., Ltd.) | | | | | |
| Curing | 2-Phenyl-4,5-dihydroxymethyl imidazole | | | 0.3 | | 0.3 |
| Accelerator | 2PHZ-PW (manufactured by Shikoku | | | | | |
| | Chemicals Corporation) | | | | | |
| | 2-Phenyl-4-methylimidazole 2P4MZ | 0.2 | 0.3 | | 0.1 | |
| | (manufactured by Shikoku Chemicals | | | | | |
| | Corporation) | | | | | |
| Silane | β-(3,4-epoxycyclohexyl)ethyl | 0.7 | 1.1 | | | 1.5 |
| coupling | trimethoxysilane KBM-403 (manufactured | | | | | |
| agent | by Shin-Etsu Chemical Co., Ltd.) | | | | | |
| | 3-aminopropyltriethoxysilane KBE-903 | | | 1.3 | 0.5 | |
| | (manufactured by Shin-Etsu Chemical Co., | | | | | |
| | Ltd.) | | | | | |
| Filling | Spherical silica filler SC1050 | 25 | 55 | 70 | | 85 |
| material | (manufactured by Admatechs Company | | | | | |
| | Limited), particle diameter: 0.25 μm | | | | | |
| Total [parts by weight] | | 100.0 | 100.0 | 100.0 | 100.0 | 100.0 |
| (B)/(C) | | 2.8 | 2.1 | 1.8 | 4.1 | 2.0 |
| Melt | 80° C. | 7700 | 18800 | 51000 | 0.03 | 128000 |
| viscosity η | 150° C. | 3800 | 9800 | 33000 | 0.01 | 107000 |
| [Pa · s] | | | | | | |

[3] Evaluation

[3-1] Evaluation of Burying Properties

Burying properties of the unevenness on the silicon wafer having the solder bump of the adhesive film in each of Examples and Comparative Examples were evaluated by presence or absence of voids in the vicinity of an uneven portion, by using a metallurgical microscope.

◯: Voids were not observed in the vicinity of the uneven portion.

X: Voids were observed in the vicinity of the uneven portion.

### [3-2] Evaluation of Bleeding (=Displacement) of Adhesive Film

The evaluation of bleeding (=displacement) of the adhesive film of each of Examples and Comparative Examples was performed by measuring a length of the compositions of the adhesive film which protrude from the edge portion of the semiconductor chip in the semiconductor device by using the metallurgical microscope, thereby performing bleeding evaluation. Symbols are as follows.

◯: The length of the displacement from the edge portion of the semiconductor chip was less than 700 μm.

X: The length of the displacement from the edge portion of the semiconductor chip was 700 μm or greater.

[3-3] Connection Reliability

Twenty semiconductor devices (for each of the adhesion temperatures) obtained using the dicing-tape-integrated adhesive sheet of each of Examples and Comparative Examples were subjected to 100 cycles of a temperature cycle test in which alternate exposure under the condition of −55° C. for 30 minutes and under the condition of 125° C. for 30 minutes was set to one cycle, and connection resistance values of the semiconductor chip and the circuit board in the semiconductor devices after the test were measured using a digital multimeter, thereby evaluating the connection reliability. Symbols are as follows.

◯: The connection resistance values of all the twenty semiconductor devices were less than 10Ω.

X: The connection resistance values of one or more semiconductor devices were 10Ω or higher.

The results are shown in Table 2.

In addition, values of (T×P)/η at each of the adhesion temperatures T are shown in Table 2.

TABLE 2

| | | | Evaluation of burying | | Evaluation of bleeding | | | |
|---|---|---|---|---|---|---|---|---|
| | (T × P)/η | | properties | | of adhesive film | | Connection reliability | |
| | T = 80° C. | T = 150° C. | T = 80° C. | T = 150° C. | T = 80° C. | T = 150° C. | T = 80° C. | T = 150° C. |
| | P = | P = | P = | P = | P = | P = | P = | P = |
| | 0.8 MPa | 0.3 MPa | 0.8 MPa | 0.3 MPa | 0.8 MPa | 0.3 MPa | 0.8 MPa | 0.3 MPa |
| Example 1 | 1.6 × 10⁶ | 2.3 × 10⁸ | ◯ | ◯ | ◯ | ◯ | ◯ | ◯ |
| Example 2 | 1.7 × 10⁴ | 2.0 × 10⁴ | ◯ | ◯ | ◯ | ◯ | ◯ | ◯ |
| Example 3 | 8.3 × 10³ | 1.2 × 10⁴ | ◯ | ◯ | ◯ | ◯ | ◯ | ◯ |
| Example 4 | 3.4 × 10³ | 4.6 × 10³ | ◯ | ◯ | ◯ | ◯ | ◯ | ◯ |
| Example 5 | 1.3 × 10³ | 1.4 × 10³ | ◯ | ◯ | ◯ | ◯ | ◯ | ◯ |
| Example 6 | 1.6 × 10⁶ | 2.3 × 10⁸ | ◯ | ◯ | ◯ | ◯ | ◯ | ◯ |
| Example 7 | 1.7 × 10⁴ | 2.0 × 10⁴ | ◯ | ◯ | ◯ | ◯ | ◯ | ◯ |
| Example 8 | 8.3 × 10³ | 1.2 × 10⁴ | ◯ | ◯ | ◯ | ◯ | ◯ | ◯ |
| Example 9 | 3.4 × 10³ | 4.6 × 10³ | ◯ | ◯ | ◯ | ◯ | ◯ | ◯ |
| Example 10 | 1.3 × 10³ | 1.4 × 10³ | ◯ | ◯ | ◯ | ◯ | ◯ | ◯ |
| Comparative | 2.1 × 10⁹ | 4.5 × 10⁹ | ◯ | ◯ | X | X | X | X |
| Example 1 | | | | | | | | |
| Comparative | 5.0 × 10² | 4.2 × 10² | X | X | ◯ | ◯ | X | X |
| Example 2 | | | | | | | | |

As is apparent from Table 2, by using the dicing-tape-integrated adhesive sheet according to the present invention, the unevenness which had occurred due to the plurality of wiring circuits and the like on the circuit board could be suitably buried with the adhesive film, and the burying properties thereof were high. In addition, the connection reliability of the semiconductor device manufactured using the adhesive film according to the present invention was particularly high. Compared to this, in Comparative Examples, satisfactory results could not be obtained.

### INDUSTRIAL APPLICABILITY

According to the present invention, a dicing-tape-integrated adhesive sheet in which connection between terminals of opposing members and encapsulating of voids between the members can be simultaneously performed, unevenness which occurs due to a plurality of wiring circuits and the like on the circuit board can be suitably buried, and thus excellent workability is achieved can be provided, and a semiconductor device, a multilayered circuit board, and an electronic component which are manufactured by using the dicing-tape-integrated adhesive sheet can be provided. Accordingly, in the present invention, a dicing-tape-integrated adhesive sheet, and a semiconductor device, a multilayered circuit board and an electronic component which are manufactured by using the dicing-tape-integrated adhesive sheet can be appropriately used.

### REFERENCE SIGNS LIST

1: interposition layer
11: outer peripheral edge
2: adhesive layer of dicing tape
21: outer peripheral portion
3,31: adhesive film
4: support film
41: outer peripheral portion
4a, 4b: base material
5: adherend
61 to 64: laminate
7: semiconductor wafer (support body)
71: semiconductor chip
8: laminate
81: cut
82: dicing blade
83: individual piece
9: wafer ring
10, 10′: dicing-tape-integrated adhesive sheet
250: die bonder
260: collet
270: table (heater)
280: machine body
400: table (push-up unit)

1. A dicing-tape-integrated adhesive sheet which has a laminated structure including an adhesive film which has a first terminal of a support body and a second terminal of an adherend that are electrically connected using solder and by which the support body and the adherend are adhered to each other and a dicing tape,
wherein, when it is assumed that an adhesion temperature when the adhesive film is adhered to a surface on which the first terminal of the support body is formed is T[° C.], a pressure applied to the adhesive film is P[Pa], and a melt viscosity of the adhesive film at the adhesion temperature is η[Pa·s], a relationship of 1.2×10³≦(T×P)η≦1.5×10⁹ is satisfied, and
the adhesion temperature T is 60 to 150° C., the pressure P is 0.2 to 1.0 MPa, and the melt viscosity η of the adhesive film at the adhesion temperature T is 0.1 to 100,000 Pa·s.

2. The dicing-tape-integrated adhesive sheet according to claim 1,
wherein an ambient pressure when the adhesive film is adhered to the surface on which the first terminal of the support body is formed is 100 kPa or less.

3. The dicing-tape-integrated adhesive sheet according to claim 1,
wherein the adhesive film contains:
(A) a phenol resin;
(B) an epoxy resin;
(C) a compound having a flux activity function; and
(D) a film-forming resin.

4. The dicing-tape-integrated adhesive sheet according to claim 3,
wherein the adhesive film contains 3 to 30 weight % of (A) the phenol resin, 10 to 80 weight % of (B) the epoxy resin, 1 to 30 weight % of (C) the compound having a flux activity function, and 1 to 50 weight % of (D) the film-forming resin.

5. The dicing-tape-integrated adhesive sheet according to claim 3,
wherein (B) the epoxy resin is in a liquid phase at 25° C.

6. The dicing-tape-integrated adhesive sheet according to claim 3,
wherein a viscosity of (B) the epoxy resin at 25° C. is 500 to 50,000 mPa·s.

7. The dicing-tape-integrated adhesive sheet according to claim 3,
wherein a blending ratio ((B)/(C)) of (B) the epoxy resin and (C) the compound having a flux activity function is 0.5 to 12.0.

8. The dicing-tape-integrated adhesive sheet according to claim 3,
wherein (C) the compound having a flux activity function is a compound having a flux activity function, which contains two phenolic hydroxyl groups in a molecule and at least one carboxyl group directly bonded to an aromatic group.

9. The dicing-tape-integrated adhesive sheet according to claim 3,
wherein (D) the film-forming resin contains a phenoxy resin.

10. The dicing-tape-integrated adhesive sheet according to claim 3,
wherein the adhesive film further contains a filling material.

11. The dicing-tape-integrated adhesive sheet according to claim 10,
wherein a content of the filling material is 0.1 weight % or higher and 80 weight % or less.

12. A semiconductor device comprising:
a cured material of the adhesive film according to claim 1.

13. A multilayered circuit board comprising:
a cured material of the adhesive film according to claim 1.

14. An electronic component comprising:
a cured material of the adhesive film according to claim 1.

15. The dicing-tape-integrated adhesive sheet according to claim 2,
wherein the adhesive film contains:
(A) a phenol resin;
(B) an epoxy resin;
(C) a compound having a flux activity function; and
(D) a film-forming resin.

16. The dicing-tape-integrated adhesive sheet according to claim 4,
wherein (B) the epoxy resin is in a liquid phase at 25° C.

17. The dicing-tape-integrated adhesive sheet according to claim 4,
wherein a viscosity of (B) the epoxy resin at 25° C. is 500 to 50,000 mPa·s.

18. The dicing-tape-integrated adhesive sheet according to claim 5,
wherein a viscosity of (B) the epoxy resin at 25° C. is 500 to 50,000 mPa·s.

19. The dicing-tape-integrated adhesive sheet according to claim 4,
wherein a blending ratio ((B)/(C)) of (B) the epoxy resin and (C) the compound having a flux activity function is 0.5 to 12.0.

20. The dicing-tape-integrated adhesive sheet according to claim 5,
wherein a blending ratio ((B)/(C)) of (B) the epoxy resin and (C) the compound having a flux activity function is 0.5 to 12.0.
